(19) United States
(12) Patent Application Publication
(10) Pub. No.: US 2025/0279360 A1
(43) Pub. Date: Sep. 4, 2025

(54) VERTICAL BACK END OF LINE TRANSISTOR AND INTEGRATION WITH MEMORY CELL

(71) Applicant: Taiwan Semiconductor Manufacturing Company, Ltd., Hsinchu (TW)

(72) Inventors: Kuo-Chang Chiang, Hsinchu City (TW); Hsin-Yu Lai, Hsinchu (TW); Chih-Yu Chang, New Taipei City (TW); Katherine H. Chiang, New Taipei City (TW)

(21) Appl. No.: 18/773,963

(22) Filed: Jul. 16, 2024

Related U.S. Application Data
(60) Provisional application No. 63/560,797, filed on Mar. 4, 2024.

(51) Int. Cl. H01L 23/528; H01L 21/28; H01L 29/51; H01L 29/66; H01L 29/78; H10B 51/10; H10B 51/20; H10B 53/10; H10B 53/20

(52) U.S. Cl. CPC H01L 23/5283; H01L 23/528; H10B 51/10; H10B 51/20; H10B 53/10; H10B 53/20; H10D 30/0415; H10D 30/701; H10D 64/033; H10D 64/689

(57) ABSTRACT

A back-end-of-line (BEOL) transistor includes a source electrode vertically stacked over a drain electrode and spaced apart from the drain electrode by a dielectric spacer between the first and second horizontal conductive layers. A semiconductor layer extends vertically between the source electrode and the drain electrode along a sidewall of the dielectric spacer. The drain electrode provides a channel for the transistor. A gate dielectric layer and a gate electrode are disposed over the gate dielectric layer. This structure allows the transistor to be manufactured without an etch process that can introduce defects into the semiconductor layer. The source electrode may be extended laterally to provide the bottom electrode of a memory cell that is integrated with the BEOL transistor.

### REFERENCE TO RELATED APPLICATIONS

This Application claims the benefit of U.S. Provisional Application No. 63/560,797, filed on Mar. 4, 2024, which is hereby incorporated by reference in its entirety.

### BACKGROUND

Integrated circuit devices may include millions or billions of transistors. The transistors are configured to act as switches and or to produce power gains so as to enable logical functionality for an integrated chip (e.g., form a processor configured to perform logic functions). Integrated chips may also include large numbers of passive devices, such as capacitors, resistors, inductors, varactors, and the like. Passive devices are widely used to control integrated chip characteristics, such as gains, time constants, etc. Active and passive devices may be used to provide memory in large scale arrays.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3 illustrate cross-sectional views of integrated circuit (IC) devices according to various embodiments of the present disclosure.

FIG. 4A-4C illustrate patterns for pits in the bottom electrode of a memory cell in accordance with various embodiments.

FIG. 5A illustrates a cross-sectional view and FIG. 5B illustrates a plan view of an IC device according to another embodiment.

FIGS. 6-17 are a series of cross-sectional views illustrating an embodiment of a method of forming IC device of the present disclosure.

FIGS. 18-22 illustrate a variation on the method of FIGS. 6-17, the variation providing an embodiment of another method of forming IC device of the present disclosure.

FIGS. 23-41B are a series of views illustrating an embodiment of a method of forming IC device of the present disclosure. Where the figures have no letter suffix or the suffix “A”, they are cross-sectional view. Where the figures have the suffix “B”, they are plan views.

FIG. 42-44 provide flow charts for various embodiments of methods of forming IC devices in accordance with the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and or letters in the various examples. This repetition is for the purpose of simplicity and clarity and does not in itself dictate a relationship between the various embodiments and or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Front-end-of-line (FEOL) transistors may be a bottleneck in the drive toward higher density non-volatile memories (NVMs). High density random access memory may dictate a write current greater than 200 μA/μm. Larger transistors or multiple transistors operated in parallel may be needed to support a current of that magnitude. For example, some designs suggest the use of two or more transistors for each memory cell to provide sufficient drive current. Those approaches pose a large FEOL area penalty.

To avoid that penalty, back-end-of-line (BEOL) transistors may be used as access control devices for memory cells. The BEOL transistors and the memory cells are disposed in the metal interconnect structure over a semiconductor substrate. Placing the access control devices within the metal interconnect structure frees up space at the semiconductor substrate surface and thereby provides added flexibility for device integration.

A BEOL transistor within a metal interconnect typically has a channel provided by a layer of oxide semiconductor. A gate for the BEOL transistor may be below the oxide semiconductor and may be separated from the oxide semiconductor by a gate dielectric. Source and drain electrodes vias contact an upper surface of the oxide semiconductor layer. The source electrode via may connect to the bottom electrode of a memory cell above the BEOL transistor.

The inventors have found that the oxide semiconductor layer may be damaged and the reliability of the BEOL transistor may be reduced by a damascene process used to form the source and drain electrode vias. In particular, the damascene process includes etching via openings for the source and drain electrode vias. The oxide semiconductor layer is exposed through the via openings. Potential issues may arise from etch chemical residues on the oxide semiconductor layer, damage due to over etching, or from hydrogen/water absorption through the via openings. These issues may lead to oxygen defect generation, additional donor states, or other phenomena that manifest in deviation of a threshold voltage of the BEOL transistor from design targets or variability in the threshold voltage among a group of BEOL transistors.

The present disclosure provides a BEOL transistor that can be easily manufactured without the problematic etch process discussed above. The BEOL transistor includes a source electrode vertically stacked over a drain electrode and spaced apart from the drain electrode by a dielectric spacer. The channel is provided by a semiconductor layer that extends vertically between the source electrode and the drain electrode along a sidewall of the dielectric spacer. A gate dielectric layer is disposed over the semiconductor layer and a gate electrode is over the gate dielectric layer. This approach results improves the quality of the oxide semiconductor layer in the BEOL transistors in a memory array, reduces source/drain contact resistances, and provides memory devices with higher reliability. Additional benefits have been realized, including the avoidance of film stacking stresses that occurred with the old approach.

In some embodiments, the drain electrode juts out from under the dielectric spacer, and the semiconductor layer has a lower horizontal portion on the jutting portion of the drain electrode. In some embodiments, the drain electrode juts out on all sides of the dielectric spacer. The semiconductor layer may have an upper horizontal portion over the source electrode. With this structure, the semiconductor layer may have no cut edges or etched surfaces in proximity to the channel. In some embodiments, some or all of the cut edges of the semiconductor layer are cover by high κ dielectric. The high κ dielectric on the cut edges may reduce leakage between the oxide semiconductor layer and the drain electrode. While the terms “source electrode” and “drain electrode” are used in this description, it will be appreciated that the structure describe as the “source electrode” may be configured as the drain electrode and the structure describe as the “drain electrode” may be configured as the source electrode.

In some embodiments, a memory cell is integrated with the BEOL transistor. In particular, the source electrode may extend laterally to provide a bottom electrode for the memory cell. In some embodiments, the memory cell and the BEOL transistor are disposed between an adjacent pair of metallization layers in the metal interconnect structure. In some embodiments, a dielectric layer or a data storage structure of the memory cell is in direct contact with the bottom electrode. In some embodiments, the source electrode is pitted in the area where it provides the bottom electrode so that the memory cell has a three-dimensional structure. The pits may be circular as in holes, linear as in trenches, or of any other suitable shape.

The memory cell can be any type of memory cell having a top electrode and a bottom electrode. In some embodiments, the memory cell is a dynamic random access memory (DRAM) cell and the internal structure of the memory cell, which is the portion of the memory cell between the bottom electrode and the top electrode, is provided by a dielectric so that the memory cell is a capacitor. In some embodiment, the dielectric is a high κ dielectric. In some embodiments, the memory cell is a ferroelectric random access memory (FeRAM) cell and the internal structure comprises a ferroelectric layer. In some embodiments, the memory cell is resistive random access memory (ReRAM) cell and the internal structure comprises a resistance switching material. In some embodiments, the memory cell is a magnetoresistive random access memory (MRAM) cell and the internal structure comprises a magnetic tunnel junction (MTJ). In some embodiments, the memory cell is a phase change memory (PCM) cell and the internal structure comprises a phase changing material. The internal structures of these memory cells are data storage structures except for the case of the capacitor in which the internal structure is simply a dielectric.

In some embodiments in which the memory cell is a capacitor, the capacitor dielectric is formed simultaneously with the gate dielectric layer so that the capacitor dielectric and the gate dielectric layer have the same composition and thickness. In some embodiments, the top electrode of the memory cell is formed simultaneously with the gate electrode of the BEOL transistor. In some embodiments, that the top electrode and the gate electrode have the same composition and thickness. In some embodiments, the top electrode and the gate electrode are planarized so that an upper surface of the top electrode is coplanar with an upper surface of the gate electrode.

In some embodiments, the BEOL transistor is one of a pair that share a gate electrode. The pair may be symmetrical about the gate electrode. In some embodiments, the dielectric spacer sidewall of the first of the pair faces the dielectric spacer sidewall of the second of the pair. The pair may be operated in parallel as one transistor equivalent to two transistors having twice the width or may be operated as two distinct transistors.

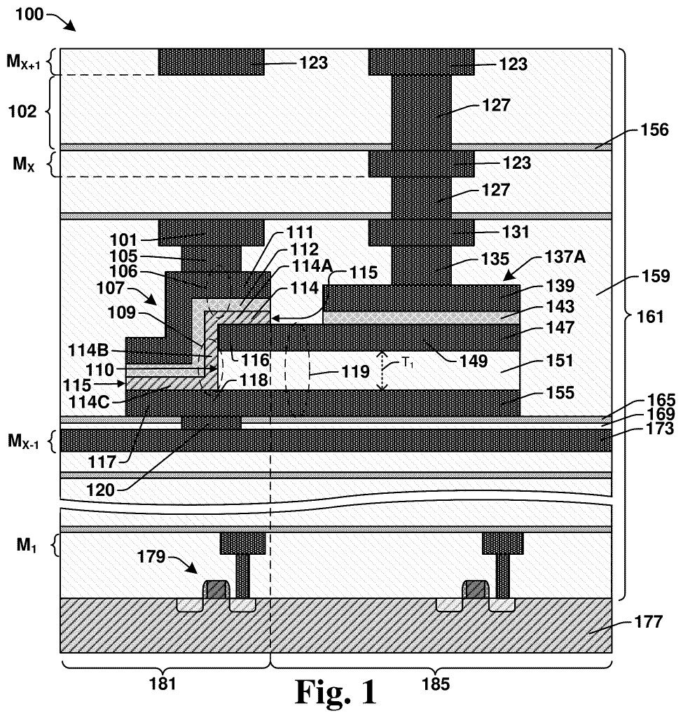

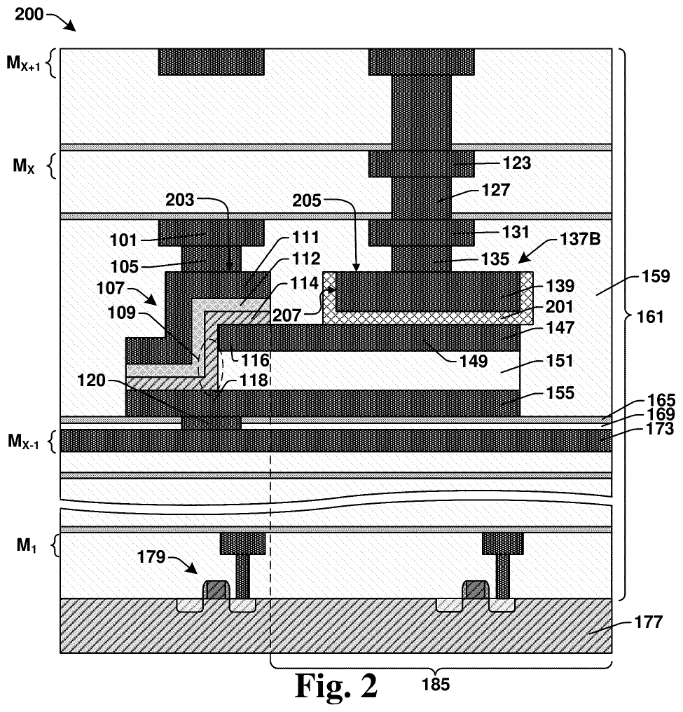

FIG. 1 illustrates an IC device 100 that includes a metal interconnect structure 161 over a substrate 177. Semiconductor devices 179 may be disposed on the substrate 177. The metal interconnect structure 161 comprises a plurality of stacked metallization layers including the metallization layers M₁, M_{X-2}, M_{X}, and M_{X+}1. The metal interconnect structure 161 may have a greater or lesser number of metallization layers than those illustrated. The metallization layers M₁, M_{X-2}, M_{X}, and M_{X+1} include wires 123. A via layer 102 and an etch stop layer 156 are disposed between each adjacent pair of the M₁, M_{X-2}, M_{X}, and M_{X+1}. The wires 123 in adjacent metallization layers may be connected by vias 127 in via layers 102.

A BEOL transistor 107 is disposed between the adjacent metallization layers M_{X-1} and M_{X}. The BEOL transistor 107 is formed by a semiconductor layer 114 and a gate stack 106 over a sidewall 110 of an electrode stack 119. The electrode stack 119 includes a first horizontal conductive layer 155, a spacer dielectric 151, and a second horizontal conductive layer 147 in a vertical stack. The gate stack 106 includes a gate dielectric layer 112 and a gate electrode 111. The BEOL transistor 107 includes a source electrode 116 provided by the second horizontal conductive layer 147, a drain electrode 118 provided by the first horizontal conductive layer 155, and a channel 109 provided by a vertical portion 114B of the semiconductor layer 114. The BEOL transistor 107 has an effective channel length that is approximately equal to a thickness T₁ of the spacer dielectric 151. In some embodiments, the thickness T₁ is in the range from about 10 nm to about 100 nm. In some embodiments, the thickness T₁ is in the range from about 10 nm to about 30 nm. These thickness provide channel lengths suitable for transistors that provide access control for memory cells. The BEOL transistor 107 may be scaled down by reducing its horizontal dimensions while maintaining a channel length of 10 nm or more so as to avoid short channel effects.

The sidewall 110 comprises the spacer dielectric 151 and the source electrode 116. The drain electrode 118 juts out from the sidewall 110. The semiconductor layer 114 includes a lower horizontal portion 114C that is over the jutting portion 117 of the drain electrode 118, a vertical portion 114B that is on the sidewall 110, and an upper horizontal portion 114A that is on top of the source electrode 116. The semiconductor layer 114 has cut edges 115. The cut edges 115 are distal from the channel 109.

A memory cell 137A is integrated with the BEOL transistor 107. In particular, the memory cell 137A is formed directly over the electrode stack 119 so that the second horizontal conductive layer 147 provides both the source electrode 116 and a bottom electrode 149 for the memory cell 137A. The source electrode 116 and the bottom electrode 149 are essentially a single structure. The memory cell 137A is a capacitor having a top electrode 139 and a dielectric layer 143 between the bottom electrode 149 and the top electrode 139. In accordance with some embodiments, the dielectric layer 143 has the same composition and thickness as the gate dielectric layer 112 and the top electrode 139 has the same composition and thickness as the gate electrode 111.

The memory cell 137A may be one in an array (not shown) of memory cells 137A for which BEOL transistors 107 provide access control. A bitline 173 for the array may be disposed in the metallization layer M_{X-1} and connected to the first horizontal conductive layer 155 by a via 120. An etch stop layer 165 and or an oxide layer 169 may be disposed between the bitline 173 and the first horizontal conductive layer 155. A word line 101 may run perpendicular to the bitline 173, may be disposed over the gate electrode 111, and may be connected to the gate electrode 111 by a via 105. The top electrode 139 may be connected to a ground rail 131 by a via 135. One or more dielectrics such as an interlevel dielectric 159 may surround and insulate these wires and vias.

FIG. 2 illustrates an IC device 200 that is like the IC device 100 of FIG. 1 except that it includes the memory cell 137B in place of the memory cell 137A. The memory cell 137B has a top electrode 139 that may be thicker than the gate electrode 111. The top electrode 139 may have an upper surface 205 that is coplanar with an upper surface 203 of the gate electrode 111. The memory cell 137B has an internal structure 201 that may be either a dielectric layer or a data storage structure. In either case, the internal structure 201 may be in direct contact with the bottom electrode 149. A data storage structure may be a ferroelectric layer, a resistive switching material layer, a magnetic tunnel junction (MTJ), a phase changing material layer, the like, or any other type data storage structure. If the memory cell 137B is a capacitor and the internal structure 201 is a dielectric layer, the dielectric layer may have a different thickness and or composition from the gate dielectric layer 112. In some embodiments, the internal structure 201 continues onto sidewalls 207 of the top electrode 139.

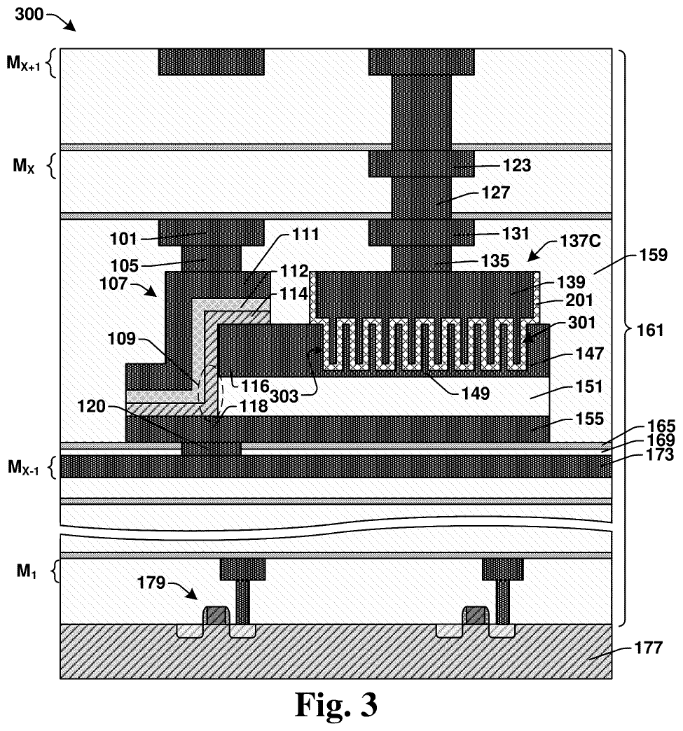

FIG. 3 illustrates an IC device 300 that is like the IC device 200 of FIG. 2 except that it includes the memory cell 137C in place of the memory cell 137B, and in the IC device 300 the bottom electrode 149 has internal sidewalls 303 that define pits 301. In the memory cell 137C, the internal structure 201 and the top electrode 139 extend into the pits 301 so that the memory cell 137C has a three-dimensional structure.

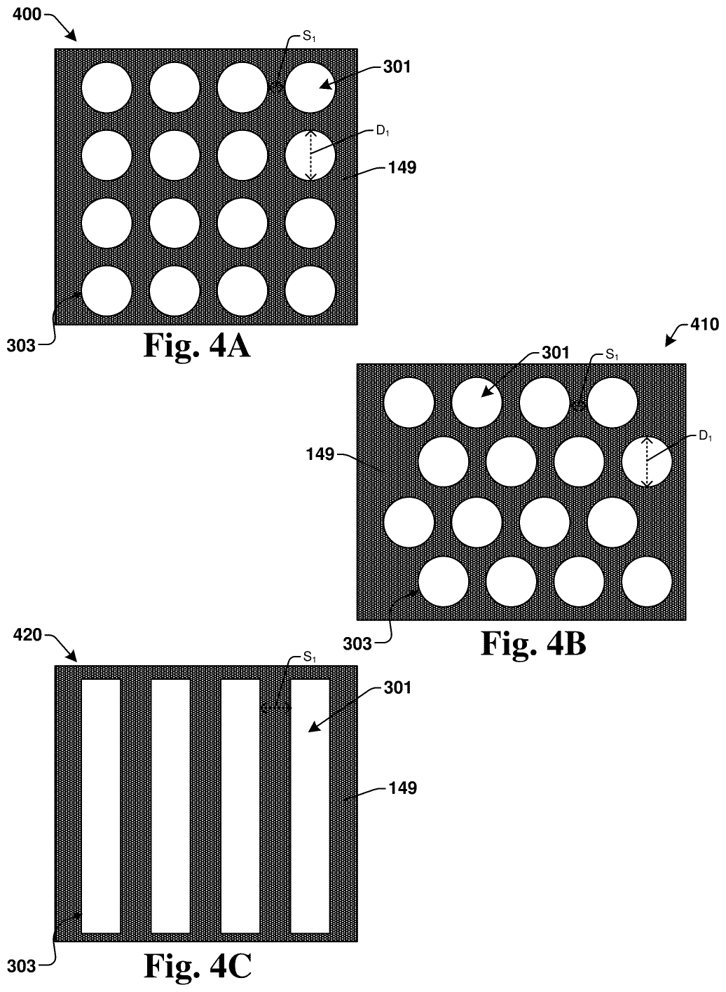

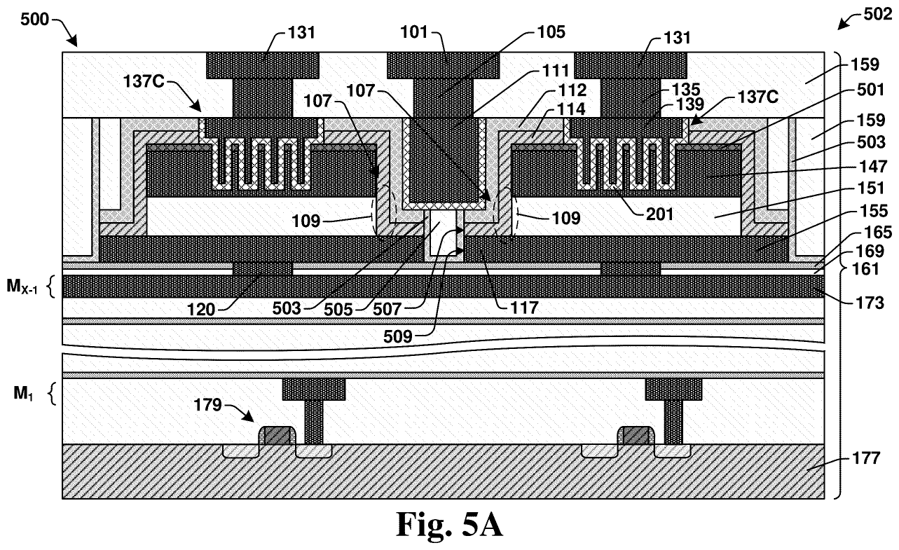

FIG. 4A provide a plan view 400 illustrating the bottom electrode 149 in accordance with a first embodiment. In the first embodiments, the pits 301 have elliptical cross-sections and form an array have n rows and m columns. Each of m and n may be separately selected and may be in the range from about 1 to about 500. In some embodiments, m and n are in the range from 2 to about 100. The depth of the pits 301 may be, for example, in the range from about 1 nm to about 100 nm. In some embodiments, the pits 301 have depths in the range from about 1 nm to about 20 nm. In some embodiments, the pits 301 have depths in the range from about 20 nm to about 100 nm. In some embodiments, the pits 301 have depths that are less than a thickness of the second horizontal conductive layer 147 (see FIG. 3).

The pits 301 may be circular with a diameter D₁ and a spacing S1. The diameter D₁ may be, for example, in the range from about 1 nm to about 100 nm. In some embodiments, the diameter D₁ is in the range from about 1 nm to about 20 nm. In some embodiments, the diameter D₁ is in the range from about 20 nm to about 100 nm. The spacing S₁ may be less than the diameter D₁. In some embodiments, the spacing S₁ is half or less the diameter D₁. In some embodiments, the pits 301 are non-circular. If the pits 301 are elliptical but non-circular, they may have a major access to minor access ratio in the range from about 1:1 to about 2:1.

FIG. 4B provide a plan view 410 illustrating the bottom electrode 149 in accordance with a second embodiment. The second embodiment of FIG. 4B is like the first embodiment of FIG. 4A except that in the embodiment of FIG. 4B the rows of pits 301 are staggered to provide narrower spacing. FIG. 4C provide a plan view 420 illustrating the bottom electrode 149 in accordance with a third embodiment. In the third embodiment, the pits 301 take the form of trenches.

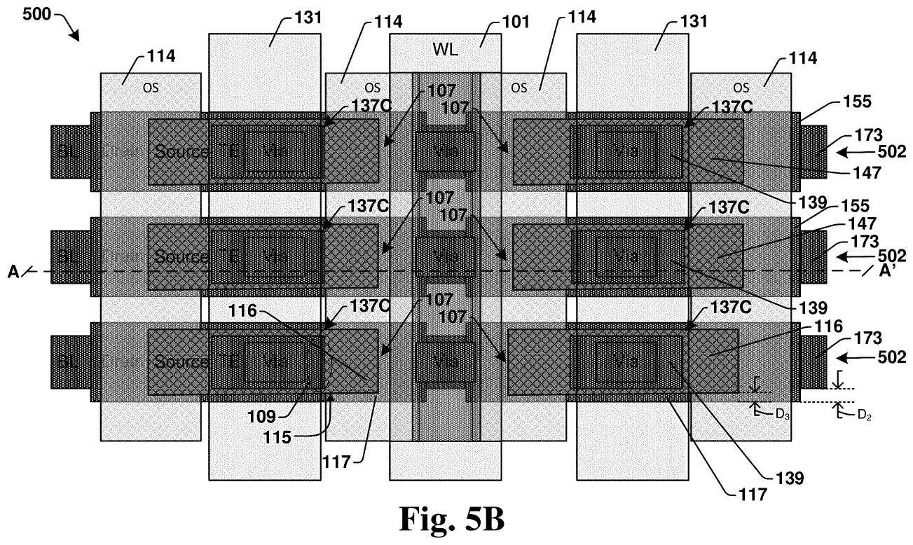

FIG. 5A provides a cross-sectional view and FIG. 5B provides a plan view of an IC device 500. The cross-sectional view of FIG. 5A illustrates a unit cell 502, which is one in an array of like cells. The cross-sectional view of FIG. 5A corresponds to the line A-A′ in the plan view of FIG. 5B. The plan view of FIG. 5B shows three of the unit cells 502. The unit cell 502 includes two BEOL transistors 107 and two memory cells 137C symmetrically arranged around a shared gate electrode 111. A high κ dielectric layer 503 covers edges 507 of the of the semiconductor layers 114 and edges 509 of the drain electrodes 118 so as to reduce leakage currents. A space between the edges 507 may be filled by an oxide layer 505. The BEOL transistors 107 in each pair may be connected in parallel to operate as one transistor.

With reference to the plan view of FIG. 5B, the drain electrodes 118 may be wider than the bitlines 173 so that they have side edges offset by a distance D₂, which is approximately half the difference in width. The distance D₂ may be in the range from about 1 nm to about 100 nm. In some embodiments, the distance D₂ is in the range from about 1 nm to about 20 nm. In some embodiments, the distance D₂ is in the range from about 20 nm to about 100 nm. The offset allows greater areas for the BEOL transistors 107 and the memory cells 137C while maintaining a spacing between the bitlines 173. If the offset is too large, the drain electrodes 118 will be too close together. If the offset is too small, either the BEOL transistors 107 will be too small or the spacing between the bitlines 173 will need to be increased so that the device density is compromised.

The source electrodes 116 may be narrower than the drain electrodes 118 so that they have side edges offset by a distance D₃, which is approximately half the difference in width. The distance D₃ may be in the range from about 1 nm to about 100 nm. In some embodiments, the distance D₃ is in the range from about 1 nm to about 20 nm. In some embodiments, the distance D₃ is in the range from about 20 nm to about 100 nm. If the offset is too large, either the BEOL transistors 107 will be too small or the spacing between the bitlines 173 will need to be increased so that the device density is compromised. If the offset is too small, the manufacturing process will be difficult to execute.

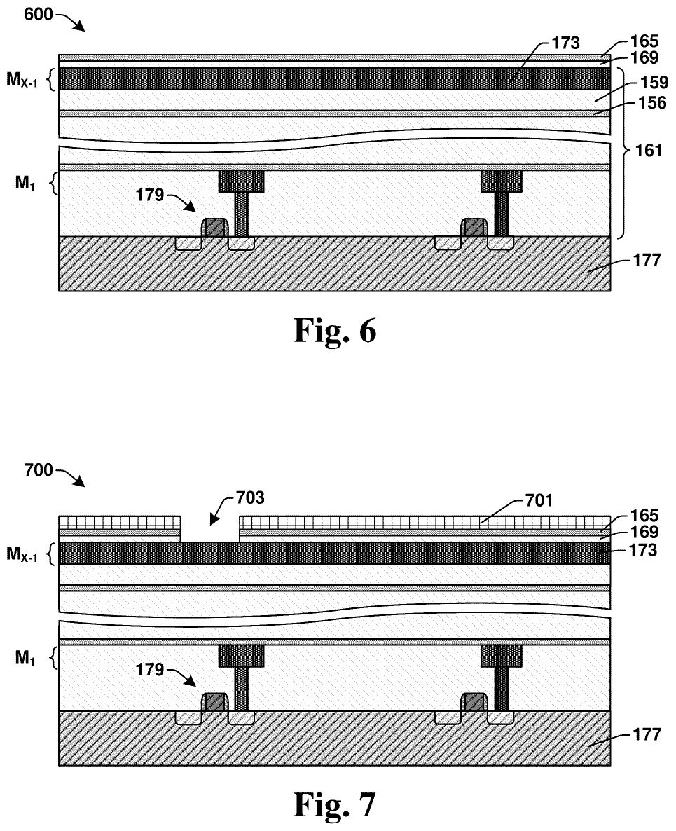

FIGS. 6-17 provide a series of cross-sectional views exemplifying a method of forming an IC device is accordance with some embodiments. While FIGS. 6-17 are described with reference to various embodiments of a method, it will be appreciated that the structures shown in FIGS. 6-17 are not limited to the method but rather may stand alone separate from the method. While FIGS. 6-17 are described as a series of acts, it will be appreciated that the order of the acts may be altered in other embodiments. While FIGS. 6-17 illustrate and describe a specific set of acts, some acts that are illustrated and or described may be omitted in some embodiments. Further, acts that are not illustrated and or described may be included. The method of FIGS. 6-17 may provide the IC device 100 of FIG. 1 or some other IC device.

As shown by the cross-sectional view 600 of FIG. 6, the method begins after provision of the substrate 177, front end of line (FEOL) processing, and formation of a first group of metallization layers M₁ to M_{X-1} of the metal interconnect structure 161. The bitline 173 is disposed in one of these metallization layers. As shown in FIG. 6, the method may begin with formation of the oxide layer 169 and the etch stop layer 165 over the metallization layer M_{X-1}. It will be appreciated that the oxide layer 169 and the etch stop layer 165 are examples, and that a different dielectric structure may be used in place of the oxide layer 169 and the etch stop layer 165.

The substrate 177 may be a semiconductor substrate. A semiconductor substrate may be a bulk semiconductor substrate or a semiconductor on insulator (SOI) substrate. At least an upper portion of a semiconductor substrate is a semiconductor. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, the semiconductor is silicon (Si) or the like. Semiconductor devices 179 may be formed on the substrate 177 during FEOL processing. The semiconductor devices 179 may be transistors, diodes, capacitors, memory cells, thyristors, resistors, the like, or any combination thereof.

The metal interconnect structure 161 may be formed using damascene or dual damascene processes. The bitline 173 and other wires 123 and vias 127 (see FIG. 1) in the metal interconnect structure 161 may include one or more layers of copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, the like, or any other suitable conductive materials. One of the layers may be a diffusion barrier layer such as titanium (Ti), tantalum (Ta), titanium nitride (TiN), tantalum nitride (TaN), or the like. The interlevel dielectric 159 may include one or more layers of silicon dioxide (SiO₂), a low K dielectric, or an extremely low K dielectric. A low K dielectric is one having a smaller dielectric constant than silicon dioxide (SiO₂). Examples of low K dielectrics include borosilicate glass (BSG), phosphorus silicate glass (PSG), borophosphosilicate glass (BPSG), fluorosilicate glass (FSG), undoped silicate glass (USG), and the like. An extremely low K dielectric is a material having a dielectric constant of about 2.1 or less. An extremely low K dielectric may be a low K dielectric with porosity that lowers its effective dielectric constant.

Adjacent metallization layer M₁−M_{X-1} may be separated by etch stop layers 156. The etch stop layers 156 may include one or more layers of aluminum oxide (AlOx), silicon nitride (SiN), silicon carbide (SiC), silicon carbonitride (SiCN), silicon oxycarbide (SIOC), silicon oxycarbonitiride (SiOCN), combinations thereof, or the like.

The oxide layer 169 may be, for example, silicon dioxide (SiO₂), a low K dielectric, or an extremely low K dielectric. The oxide layer 169 may be deposited by ALD, CVD, PVD, the like, or any other suitable processes. The etch stop layer 165 may be, for example, aluminum oxide (AlOx), silicon nitride (SiN), silicon carbide (SiC), silicon carbonitride (SiCN), silicon oxycarbide (SIOC), silicon oxycarbonitiride (SiOCN), combinations thereof, or the like. These layers may be deposited by physical vapor deposition (PVD), chemical vapor deposition (CVD), atomic layer deposition (ALD), the like, or another suitable process(es).

As shown by the cross-sectional view 700 of FIG. 7, the method may continue with formation of a mask 701 and using it to etch a via opening 703 though the etch stop layer 165 and the oxide layer 169. The mask 701 and other masks used in processes of this disclosure may be or comprise a photoresist, a hard mask, or the like and may be patterned by photolithography, ion beam lithography, the like, or some other suitable process. The etch process may be a dry etch such as a plasma etch, the like, or some other suitable etch process. After the etch process, the mask 701 may be stripped.

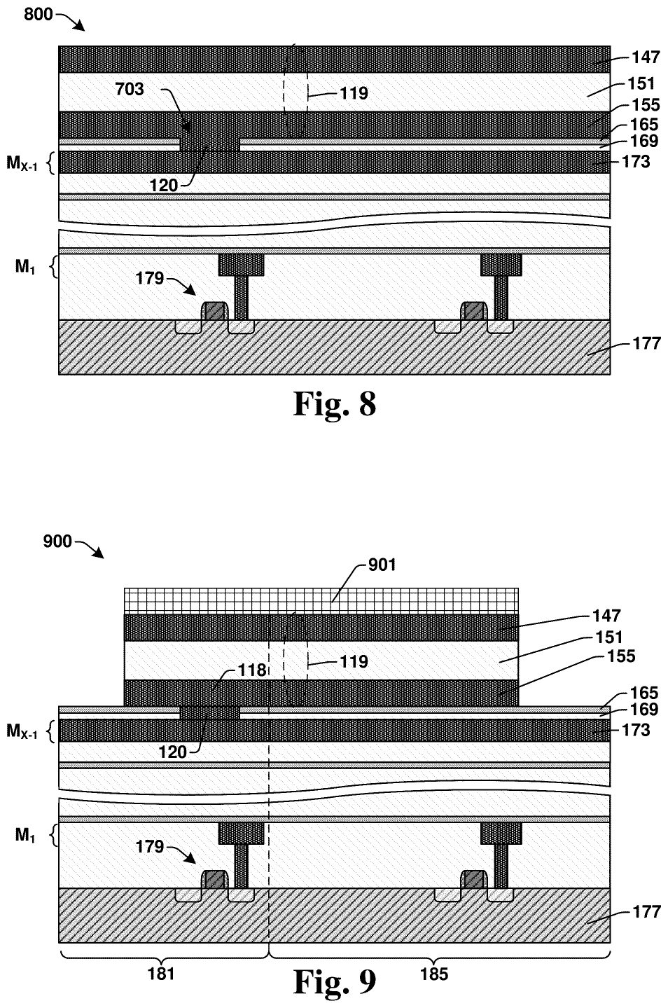

As shown by the cross-sectional view 800 of FIG. 8, the electrode stack 119 may be deposited over the structure shown by the cross-sectional view 700 of FIG. 7. The electrode stack 119 includes the first horizontal conductive layer 155, the spacer dielectric 151, and the second horizontal conductive layer 147. The first horizontal conductive layer 155 may deposit in the opening 703 to provide the via 120. The second horizontal conductive layer 147 and the first horizontal conductive layer 155 may have thicknesses in the range from about 5 nm to about 100 nm. In some embodiments, these layers have thicknesses in the range from about 5 nm to about 25 nm. In some embodiments, these layers have thicknesses in the range from about 25 nm to about 100 nm. Each of these layers may comprise one or more layers of molybdenum (Mo), titanium (Ti), tungsten (W), copper (Cu), ruthenium (Ru), chromium (Cr), nickel (Ni), titanium nitride (TiN), tantalum nitride (TaN), or the like, a conductive oxide such as indium oxide (InO), indium tin oxide (InSnO), or the like, a combination of the foregoing, or any other suitable conductive materials. In some embodiments, the second horizontal conductive layer 147 includes a top metal layer of titanium nitride (TiN), tantalum nitride (TaN), or the like. The top metal layer may have thicknesses in the range from about 5 nm to about 50 nm. The conductive layers may be deposited by PVD, CVD, ALD, electroplating, electroless plating, the like, or any other suitable process(es).

The spacer dielectric 151 may be silicon dioxide (SiO₂), silicon oxynitride (SiON), the like, or any other suitable dielectric(s). The spacer dielectric 151 may have a thickness in the range from about 10 nm to about 100 nm. In some embodiments, the spacer dielectric 151 has a thickness in the range from about 10 nm to about 30 nm. In some embodiments, the spacer dielectric 151 has a thickness in the range from about 30 nm to about 100 nm. The spacer dielectric 151 may be deposited by PVD, CVD, ALD, the like, or any other suitable process.

As shown by the cross-sectional view 900 of FIG. 9, a mask 901 may be formed and used to pattern the electrode stack 119. This patterning process defines the drain electrode 118 from the first horizontal conductive layer 155. The patterning process may be a dry etch such as a plasma etch, the like, or some other suitable etch process.

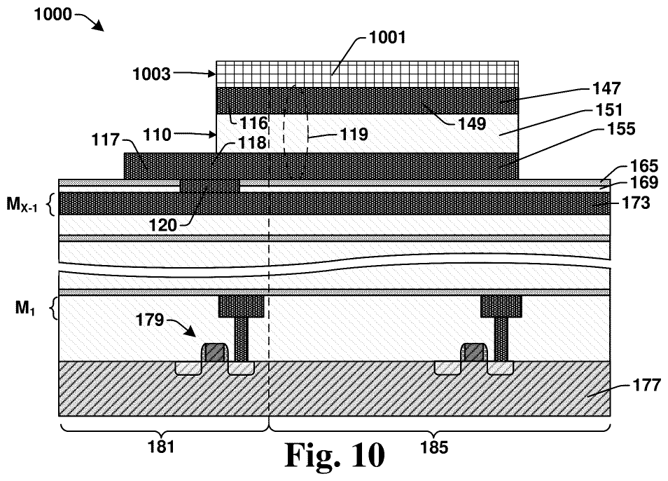

As shown by the cross-sectional view 1000 of FIG. 10, a mask 1001 may be formed and used to further pattern and upper portion of the electrode stack 119 that includes the second horizontal conductive layer 147 and the spacer dielectric 151. Optionally, the mask 1001 is formed by trimming the mask 901. This patterning process creates the sidewall 110, which includes the second horizontal conductive layer 147 and the spacer dielectric 151. The sidewall 110 be in alignment with an edge 1003 of the mask 1001. This patterning process also shapes the source electrode 116, which also provides the bottom electrode 149, from the second horizontal conductive layer 147. A difference in the shape of the mask 1001 from the shape of the mask 901 (see FIG. 9) exposes the jutting portion 117 of the drain electrode 118. The patterning process may be a dry etch such as a plasma etch, the like, or some other suitable etch process. After the etch process, the mask 1001 may be stripped.

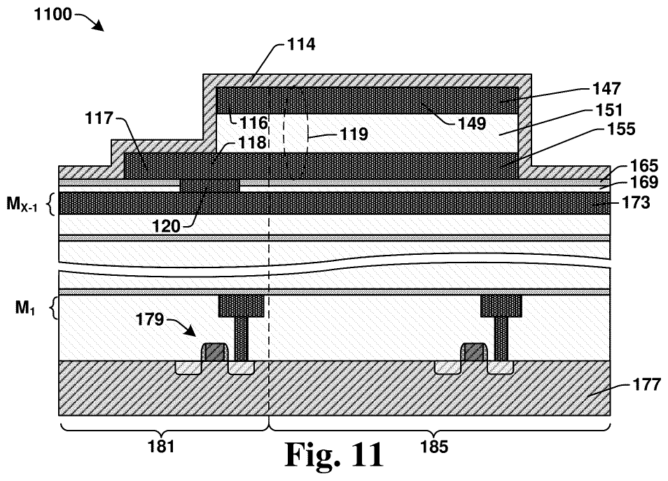

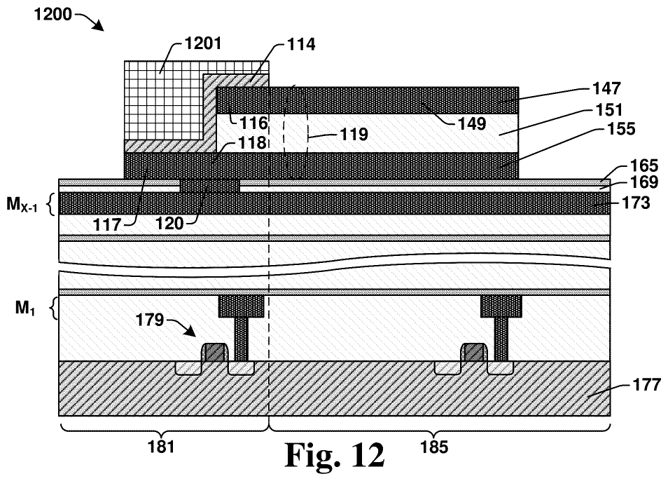

As shown by the cross-sectional view 1100 of FIG. 11, the semiconductor layer 114 may be formed over the structure shown by the cross-sectional view 1000 of FIG. 10 so that the semiconductor layer 114 is brought into contact with source electrode 116 and the drain electrode 118 without causing etch damage to the semiconductor layer 114. As shown by the cross-sectional view 1200 of FIG. 12, a mask 1201 may be formed and used to pattern the semiconductor layer 114. Patterning removes the semiconductor layer 114 from a second region 185 while leaving a portion of the semiconductor layer 114 in a first region 181. The semiconductor layer 114 may be deposited by PVD, CVD, ALD, the like, or any other suitable process. Alternatively, the semiconductor layer 114 be selectively grown in areas where the semiconductor layer 114 is desired.

The semiconductor layer 114 may be an oxide semiconductor or the like. In some embodiments, the oxide semiconductor has the formula InₓGa_{y}Zn_{z}MO, where M is titanium (Ti), aluminum (Al), silver (Ag), tungsten (W), cerium (Ce), or tin (Sn) and x is in the range from 0 to 1, y is in the range from 0 to 1, and z is in the range from 0 to 1. Examples include indium gallium oxide (IGO), indium zinc oxide (IZO), indium tungsten oxide (IWO), indium gallium zinc oxide (IGZO), zinc oxide (ZnO), aluminum zinc tin oxide (AZTO), indium titanium oxide (InTiO), gallium zinc oxide (GZO), indium oxide (InO₂), gallium oxide (Ga₂O₃), and the like, with or without tin (Sn) or other dopants. The semiconductor layer 114 may have a thickness in the range from about 3 nm to about 50 nm. In some embodiments, the thickness is in the range from about 3 nm to about 10 nm. In some embodiments, the thickness is in the range from about 10 nm to about 50 nm.

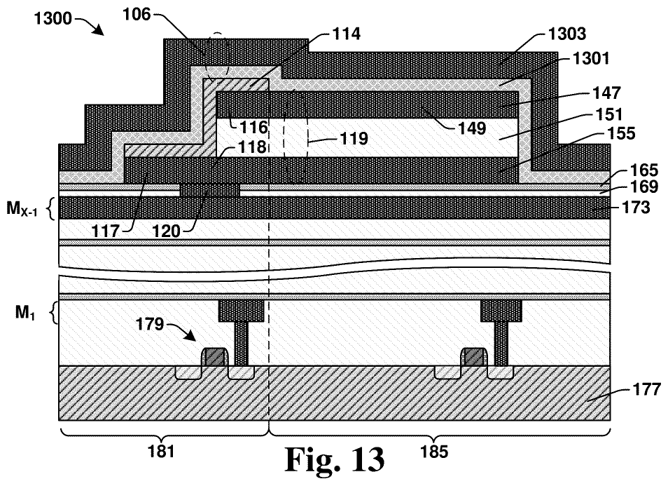

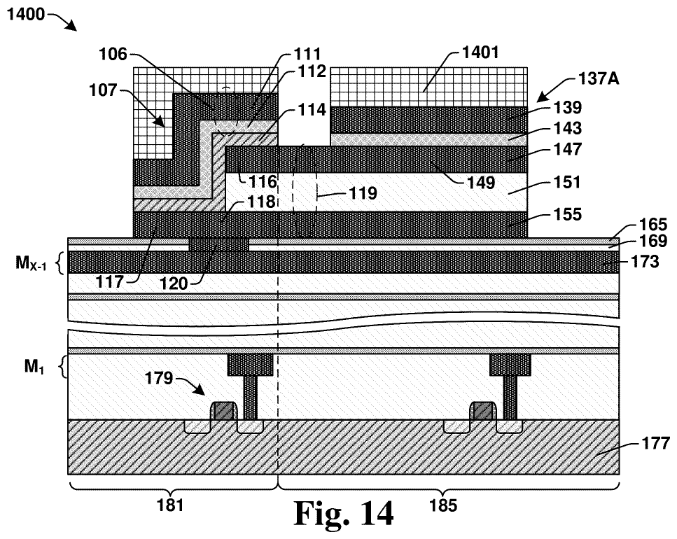

As shown by the cross-sectional view 1300 of FIG. 13, the gate stack 106 may be formed over the structure shown by the cross-sectional view 1200 of FIG. 12. The gate stack 106 includes a gate dielectric layer 1301 and a gate electrode layer 1303. In some embodiments, the gate dielectric layer 1301 is a high κ dielectric. Examples of high κ dielectrics include zirconium oxide (ZrO₂), hafnium oxide (HfO₂), hafnium silicon oxide (HfSiO), hafnium titanium oxide (HfTiO), hafnium lanthanum oxide (HfLaO), hafnium silicon oxide (HfSiO), hafnium tantalum oxide (HfTaO), hafnium zirconium oxide (HfZrO), and the like. Some additional examples include hafnium titanium oxide (HfTiO), hafnium oxide aluminum oxide (HfO₂-Al₂O₃) alloy, tantalum oxide (Ta₂O₅), aluminum oxide (Al₂O₃), yttrium oxide (Y₂O₃), lanthanum oxide (La₂O₃), strontium titanium oxide (SrTiO₃), and the like. In some embodiments, the high K dielectric has a dielectric constant of about 6 or more. The gate dielectric layer 1301 may have a thickness in the range from about 3 nm to about 50 nm. In some embodiments, the thickness is in the range from about 3 nm to about 10 nm. In some embodiments, the thickness is in the range from about 10 nm to about 50 nm. The gate dielectric layer 1301 may be deposited by ALD, CVD, PVD, the like, or any suitable process.

The gate electrode layer 1303 may be or comprise one or more layers of conductors. The conductors may be metals such as tungsten (W), titanium nitride (TiN), tantalum nitride (TaN), ruthenium (Ru), nickel (Ni), and the like or conductive oxides such as indium oxide (InO), indium tin oxide (InSnO), or the like, or any other suitable conductive material(s). The gate electrode layer 1303 may have a thickness in the range from about 5 nm to about 100 nm. In some embodiments, the gate electrode layer 1303 has a thickness in the range from about 5 nm to about 25 nm. In some embodiments, the gate electrode layer 1303 has a thickness in the range from about 25 nm to about 100 nm. The gate electrode layer 1303 may be deposited by PVD, CVD, ALD, electroplating, electroless plating, the like, or any other suitable process(es).

As shown by the cross-sectional view 1400 of FIG. 14, a mask 1401 may be formed and an etch process carried out to pattern the gate stack 106. Etching separates the gate electrode 111 from the top electrode 139, both of which are patterned from the gate electrode layer 1303 (see FIG. 13). A first portion of the gate dielectric layer 1301 that is in the first region 181 provides the gate dielectric layer 112 of the BEOL transistor 107 and a second portion of the gate dielectric layer 1301 that is in the second region 185 provides the dielectric layer 143 of the memory cell 137A. The second horizontal conductive layer 147 provides both the source electrode 116 of the BEOL transistor 107 and the bottom electrode 149 of the memory cell 137A. Etching stops in or before the second horizontal conductive layer 147 so that the source electrode 116 and the bottom electrode 149 remain a single undivided structure. After etching, the mask 1401 may be stripped.

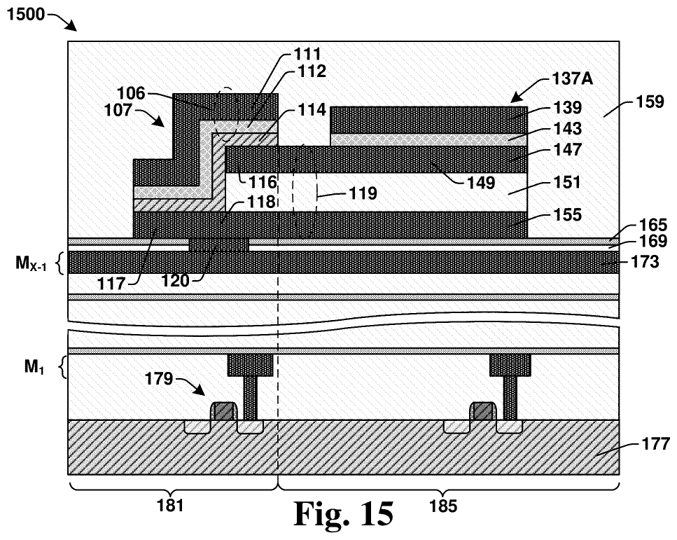

As shown by the cross-sectional view 1500 of FIG. 15, a layer of the interlevel dielectric 159 may be formed over the structure shown by the cross-sectional view 1400 of FIG. 14. The interlevel dielectric 159 may be one or more layer of dielectrics such as silicon oxide, a low K dielectric (dielectric constant less than 3.9), or an extremely low K dielectric (dielectric constant 2.1 or less). The interlevel dielectric 159 may be deposited by PVD, CVD, the like, or any other suitable process. A planarization process such as chemical mechanical polishing (CMP) may be carried out after the deposition.

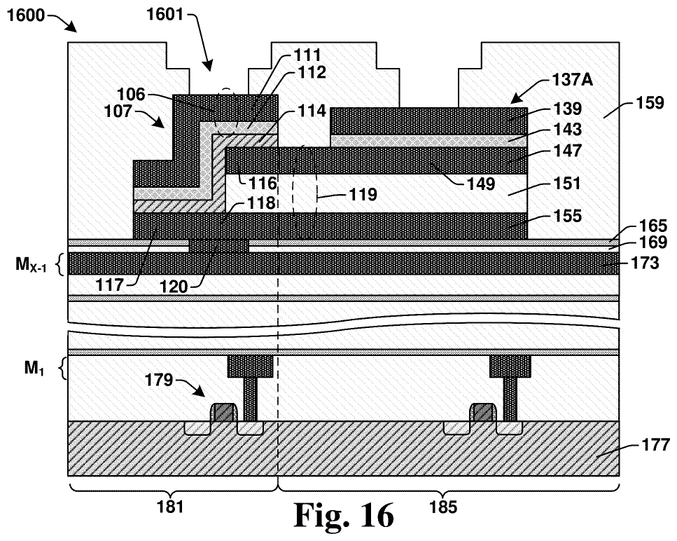

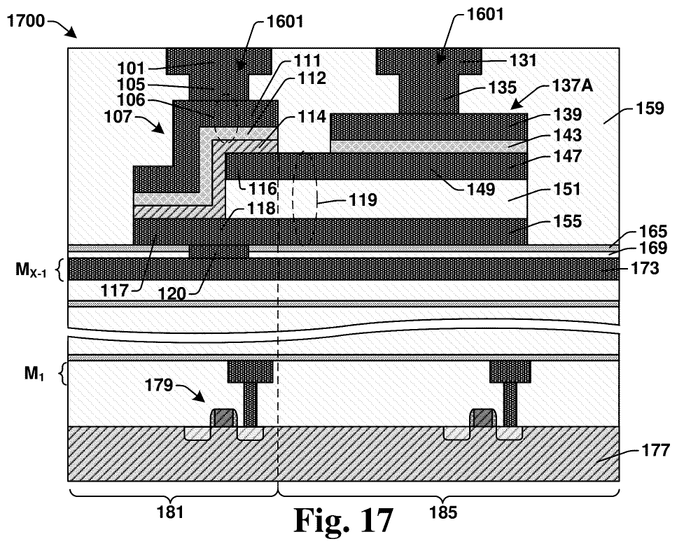

As shown by the cross-sectional view 1600 of FIG. 16, the interlevel dielectric 159 may be patterned with opening 1601. As shown by the cross-sectional view 1700 of FIG. 17, the openings 1601 may be filled with metal to provide vias 105 and 135, the word line 101, and the ground rail 131. The metal may be copper (Cu), tungsten (W), aluminum (Al), titanium (Ti) tantalum (Ta), the like, or any other suitable metal. The metal may be deposited by CVD, PVD, electroplating, electroless plating, or the like. After deposition, excess metal may be removed by a planarization process such as CVD or the like.

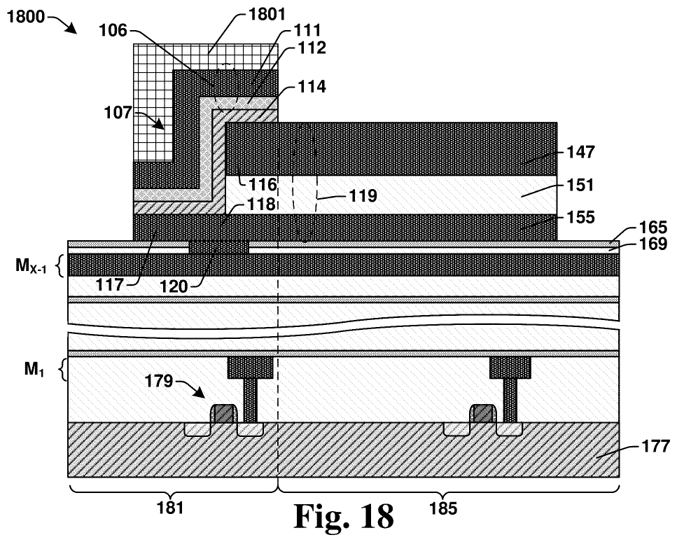

FIGS. 18-22 provide a series of cross-sectional views exemplifying a variation on the method illustrated by the cross-sectional views of FIGS. 6-17. This variation may provide the IC device 200 of FIG. 2 or some other IC device in which the internal structure 201 of the memory cell has a distinct composition from the gate dielectric layer 112 (see FIG. 2).

The variation may begin from where the gate stack 106 has been deposited as shown by the cross-sectional view 1300 of FIG. 13. As shown by the cross-sectional view 1800 of FIG. 18, in this variation the gate stack 106 is patterned with a mask 1801 so that the gate stack 106 is removed from the second region 185. The gate stack 106 may be patterned to the footprint of the semiconductor layer 114. Optionally, the semiconductor layer 114 is patterned together with the gate stack 106.

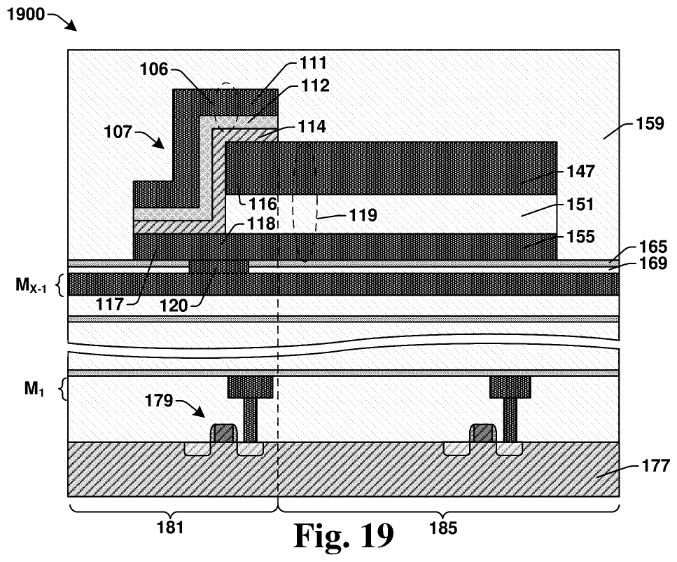

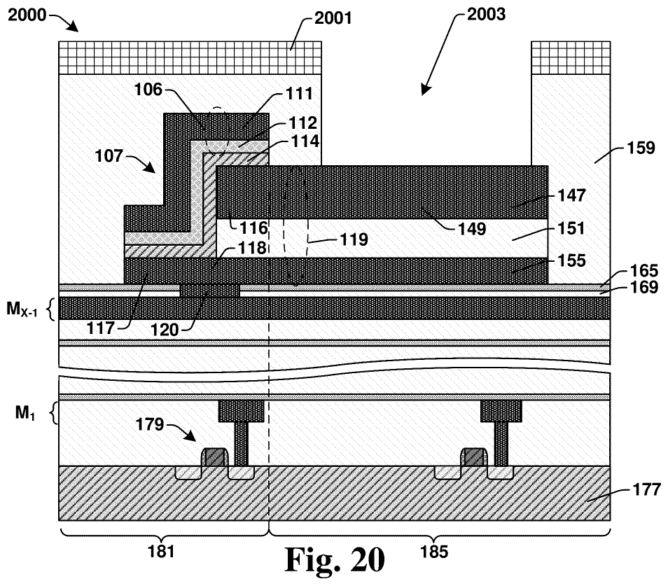

As shown by the cross-sectional view 1900 of FIG. 19, a layer of the interlevel dielectric 159 is formed over the structure shown by the cross-sectional view 1800 of FIG. 18. As shown by the cross-sectional view 2000 of FIG. 20, a mask 2001 may be formed and used to etch an opening through the interlevel dielectric 159 over the bottom electrode 149 in the second region 185.

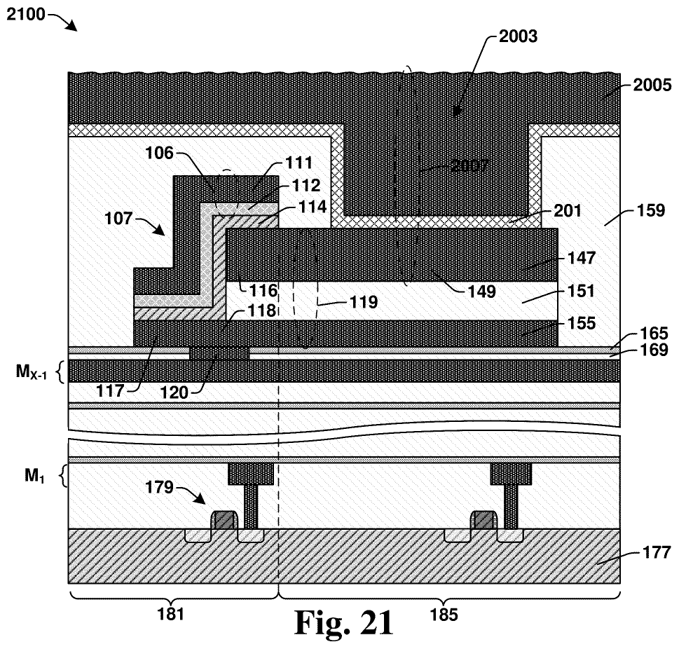

As shown by the cross-sectional view 2100 of FIG. 21. The internal structure 201 and top electrode metal layer 2005 may be deposited so as to fill the opening 2003. The bottom electrode 149, the internal structure 201, top electrode metal layer 2005 together form a memory cell stack 2007. Examples of materials suitable for the top electrode metal layer 2005 include materials suitable for the second horizontal conductive layer 147 and materials suitable for the gate electrode 111. The composition and thickness of the internal structure 201 depend on the type of memory cell to be formed. If the memory cell is a DRAM memory cell, the internal structure 201 is a dielectric such as a high κ dielectric.

If the memory cell is an FeRAM memory cell, the internal structure 201 comprises a ferroelectric material. The ferroelectric material may be, for example, a binary oxide, a ternary oxide, or a quaternary oxide. In some embodiments the ferroelectric material is a binary oxide such as hafnium oxide (HfOₓ) or the like. In some embodiments the ferroelectric material is a ternary oxide such as hafnium silicate (HfSiOₓ), hafnium zirconate (HfZrOₓ), barium titanate (BaTiO₃), lead titanate (PbTiO₃), strontium titanate (SrTO₃), calcium manganite (CaMnO₃), bismuth ferrite (BiFeO₃), aluminum scandium nitride (AlScN), aluminum gallium nitride (AlGaN), aluminum yttrium nitrate, silicon doped hafnium oxide, zirconium doped hafnium oxide, yttrium doped hafnium oxide, aluminum doped hafnium oxide, gadolinium doped hafnium oxide, strontium doped hafnium oxide, lanthanum doped hafnium oxide, scandium doped hafnium oxide, germanium doped hafnium oxide, a combination thereof, or the like. In some embodiments the ferroelectric material is a quaternary oxide such as lead zirconate, barium strontium titanate (BaSrTiOₓ), strontium bismuth tantalate or the like.

If the memory cell is an ReRAM memory cell, the internal structure 201 comprises a resistive switching material. Examples of resistive switching materials include binary transition metal oxides such as nickel oxide (NiO), titanium dioxide (TiO₂), copper oxide (CuOx) and the like, transition metal sulfides such as copper sulfide (CuS) and the like, perovskites such as strontium titanate (SrTiO), praseodymium calcium manganite (PCMO), and the like, organic charge transfer complexes such as copper-tetracyanoquinodimethane (CuTCNQ) and the like, organic donor—acceptor systems such as Ag-I-dicyanovinylidene (AIDCN) and the like.

If the memory cell is a conductive bridging (CBRAM) memory cell, the internal structure 201 comprises a solid-state electrolyte. Example of solid-state electrolytes include germanium selenium (GeSe), silver oxide (AgO), and the like.

If the memory cell a PCRAM memory cell, the internal structure 201 comprises a phase change material. Examples of phase change materials include chalcogenides such as germanium antimony tellurium (GeSbTe) silver indium antimony tellurium (AgInSbTe), and the like

If the memory cell is a MRAM memory cell, is to be formed cell the internal structure 201 comprises an MTJ. An MTJ comprises two ferromagnetic layers separated by a tunnel barrier layer. The ferromagnetic layers include a pinned layer and a free layer. Example of materials that may be suitable for the pinned layer include cobalt (Co), iron (Fe), boron (B), nickel (Ni), ruthenium (Ru), iridium (Ir), platinum (Pt), and the like. Example of materials that may be suitable for the tunnel barrier layer include magnesium oxide (MgO), aluminum oxide (AlO), nickel oxide (NiO), gadolinium oxide (GdO), tantalum oxide (TaO), molybdenum oxide (MoO), titanium oxide (TiO), tungsten oxide (WO), and the like. Example of materials that may be suitable for the free layer include cobalt (Co), iron (Fe), boron (B), iron cobalt (FeCo), nickel cobalt (NiCo), cobalt iron boride (CoFeB), iron boride (FeB), iron platinum (FePt), iron palladium (FePd), and the like.

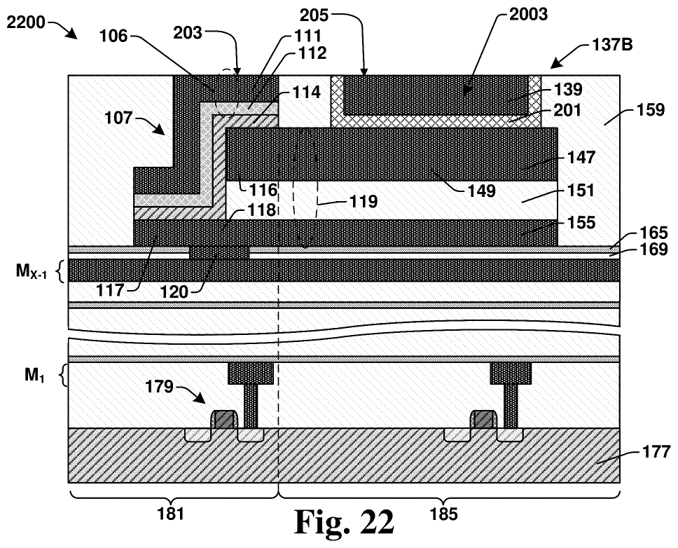

As shown by the cross-sectional view 2200 of FIG. 22, a planarization process may be carried out to remove portions of the top electrode metal layer 2005 that deposited outside the opening 2003. The portion of the top electrode metal layer 2005 that remains in the opening 2003 provide the top electrode 139. The planarization process may be CMP or the like. Planarization may leave the upper surface 205 of the top electrode 139 coplanar with the upper surface 203 of the gate electrode 111.

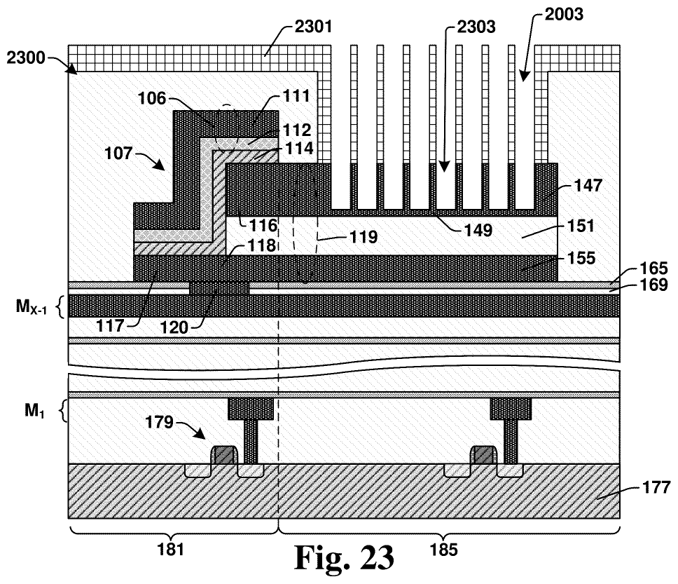

FIGS. 23-25 provide a series of cross-sectional views exemplifying a variation on the method illustrated by the cross-sectional views of FIGS. 18-22. This variation may provide the IC device 300 of FIG. 3 or some other IC device in which the memory cell 137C has a three-dimensional structure.

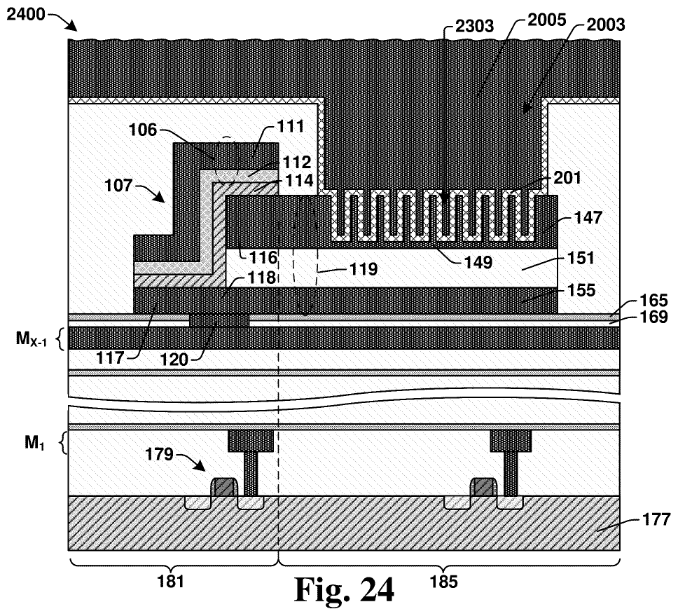

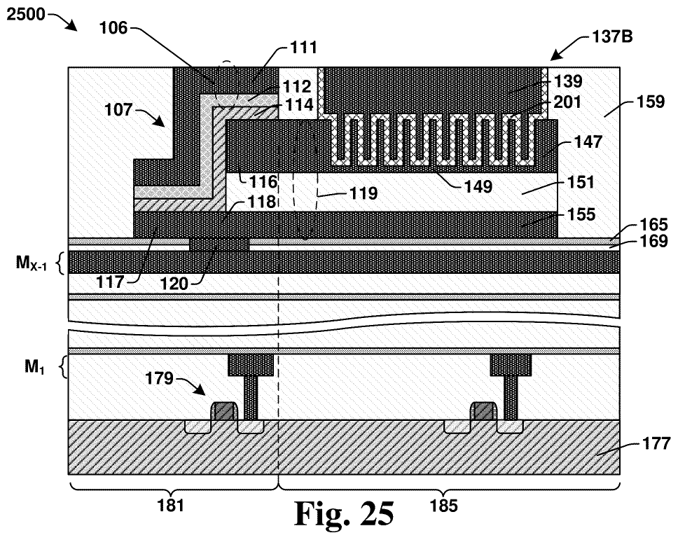

The variation may begin after etching the opening 2003, which is shown by the cross-sectional view 2000 of FIG. 20. As shown by the cross-sectional view 2300 of FIG. 23, in the present variation another mask 2301 is formed and used to etch pits 2303 in the second horizontal conductive layer 147. The pits 2303 may go part way through or entirely through the second horizontal conductive layer 147. As shown by the cross-sectional view 2400 of FIG. 24, when the internal structure 201 and the top electrode metal layer 2005 are deposited in the opening 2003, the internal structure 201 lines the pits 2303 and the top electrode metal layer 2005 extends into the pits 2303. The process may continue with planarization as shown by the cross-sectional view 2500 of FIG. 25.

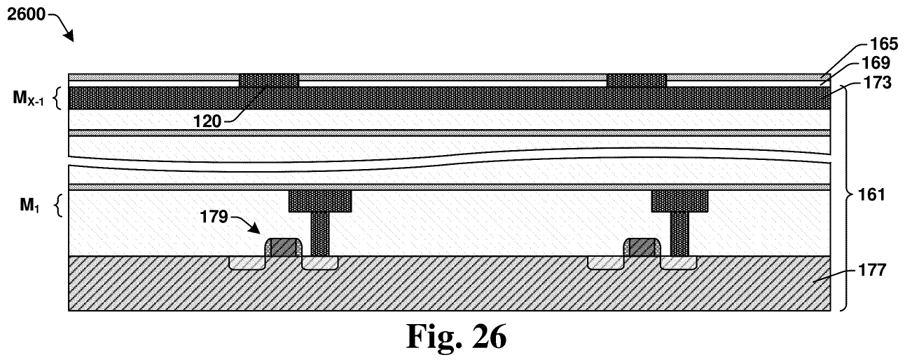

FIGS. 26-41 provide a series of views exemplifying a method of forming an IC device is accordance with some embodiments. While FIGS. 26-41 are described with reference to various embodiments of a method, it will be appreciated that the structures shown in FIGS. 26-41 are not limited to the method but rather may stand alone separate from the method. While FIGS. 26-41 are described as a series of acts, it will be appreciated that the order of the acts may be altered in other embodiments. While FIGS. 26-41 illustrate and describe a specific set of acts, some acts that are illustrated and or described may be omitted in some embodiments. Further, acts that are not illustrated and or described may be included. The method of FIGS. 26-41 may provide the IC device 500 of FIG. 5A or some other IC device.

As shown by the cross-sectional view 2600 of FIG. 26, the method may begin with formation of the vias 120 through the oxide layer 169 and the etch stop layer 165 (or other dielectric structure) to make connections to the bitline 173. The vias 120 may be formed by a damascene process or some other suitable process.

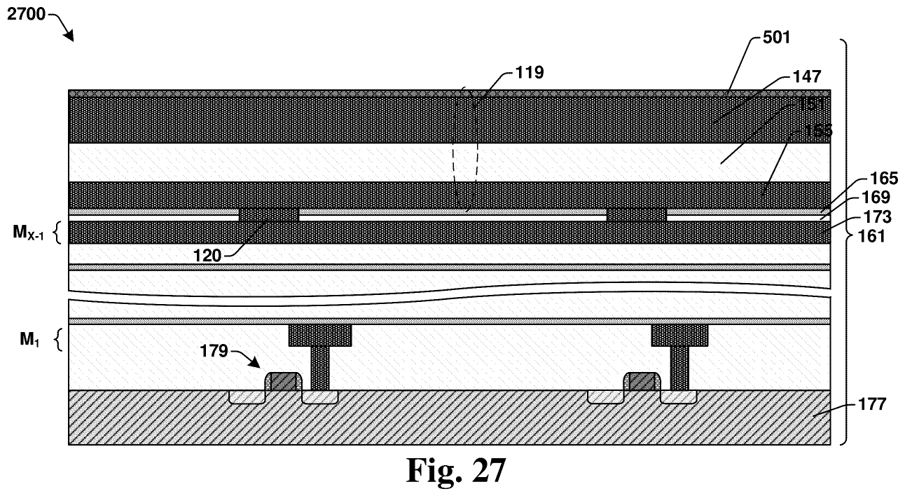

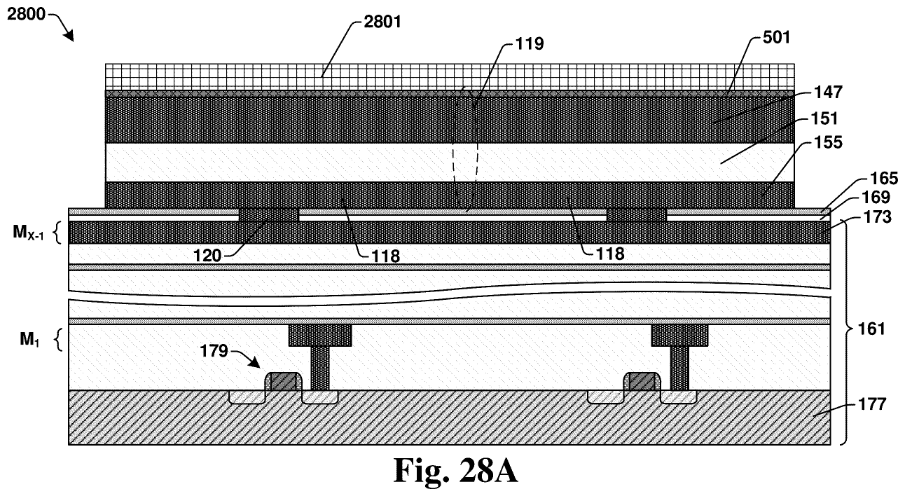

As shown by the cross-sectional view 2700 of FIG. 27, the method may continue with formation of the electrode stack 119. The electrode stack 119 includes the first horizontal conductive layer 155, the spacer dielectric 151, and the second horizontal conductive layer 147. In this example, the second horizontal conductive layer 147 includes a top metal layer 501.

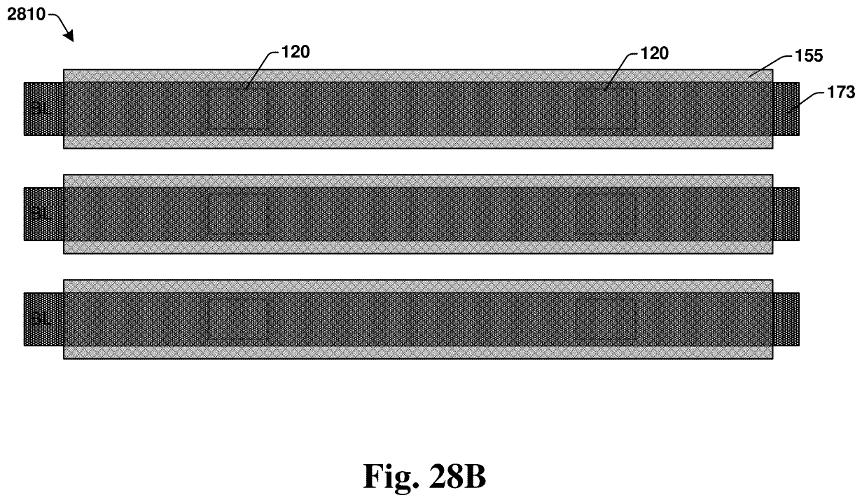

As shown by the cross-sectional view 2800 of FIG. 28A and the plan view 2810 of FIG. 28B, a mask 2801 may be formed and an etch process carried out to pattern the electrode stack 119. This patterning process may shape the drain electrodes 118.

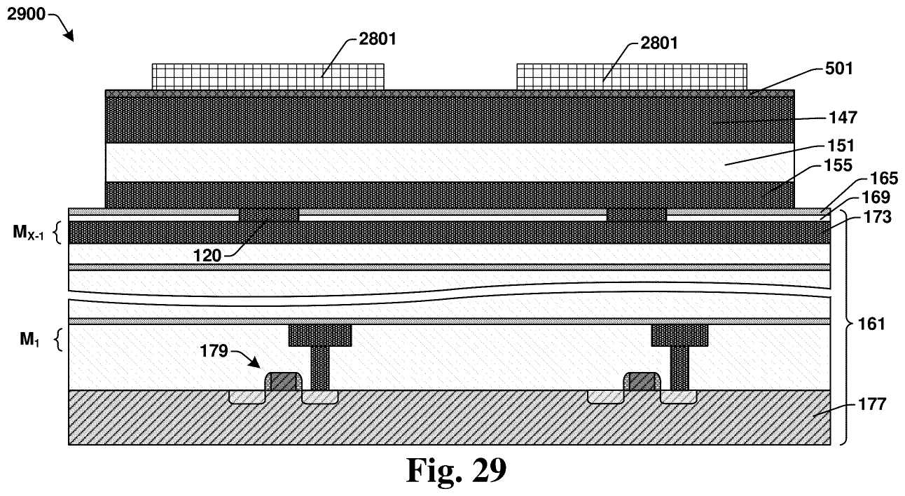

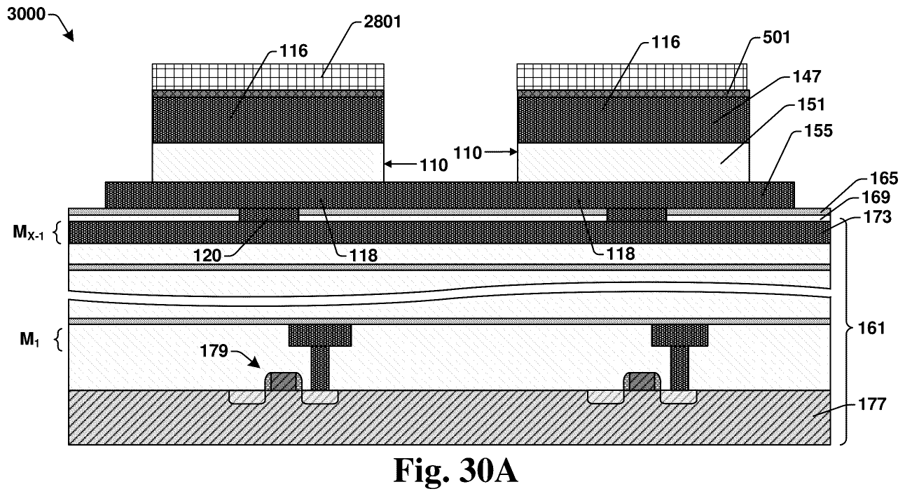

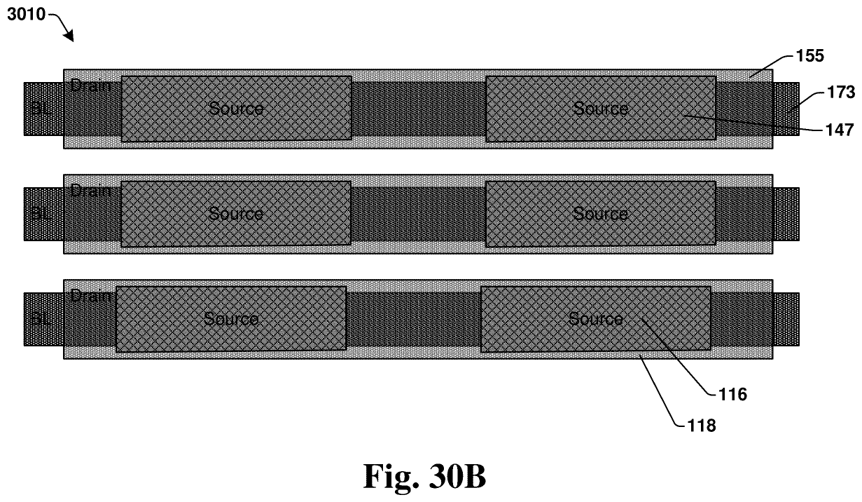

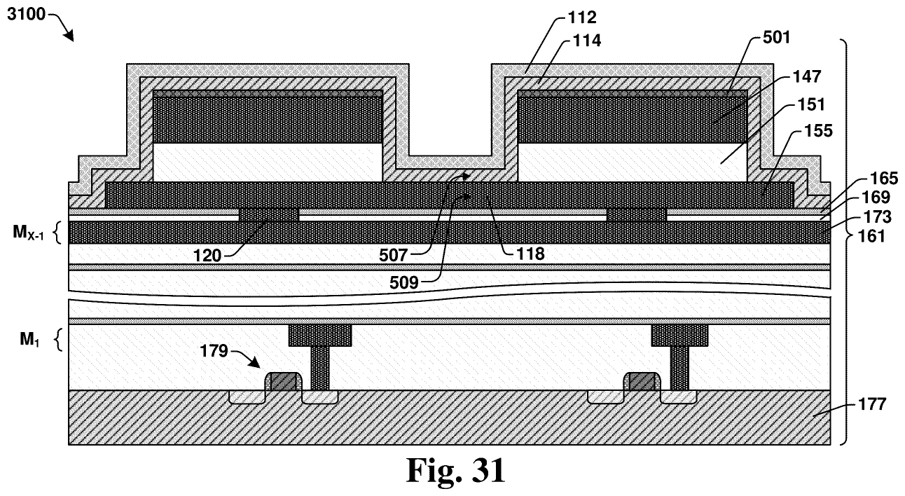

As shown by the cross-sectional view 2900 of FIG. 29, the mask 2801 may be trimmed. Trimming may include exposing and developing a photoresist. As shown by the cross-sectional view 3000 of FIG. 30A and the plan view 3010 of FIG. 30B, after trimming another etch process may be carried out with the mask 2801. This etch process may stop on the first horizontal conductive layer 155, may shape the source electrode 116, and may create sidewalls 110.

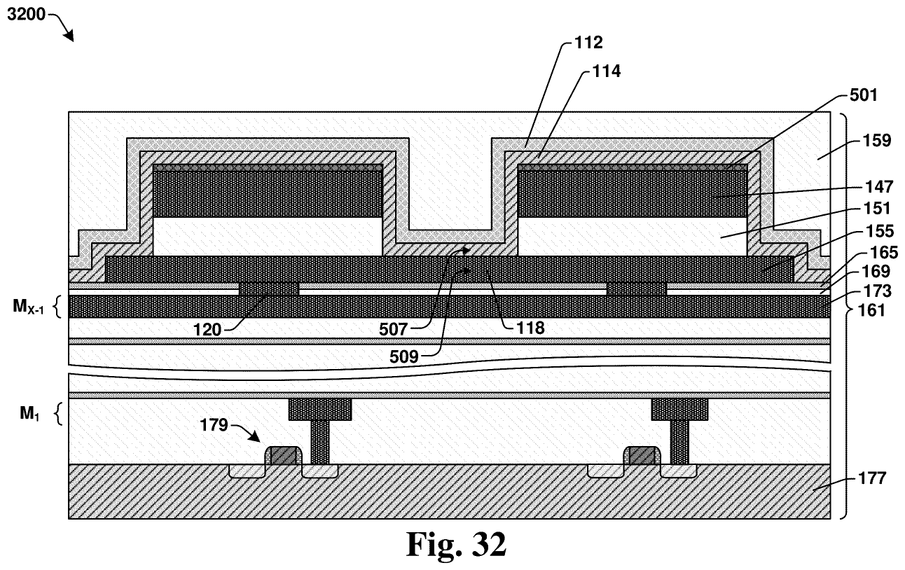

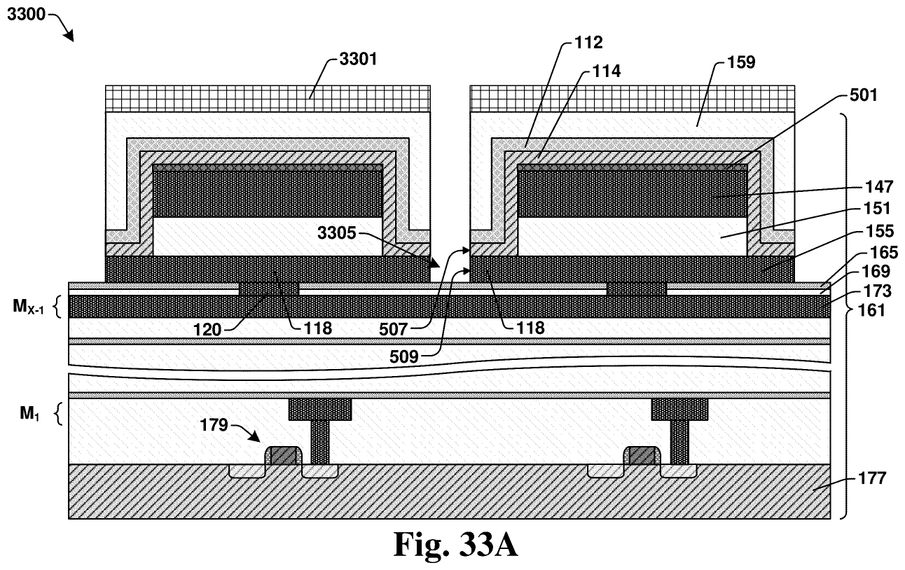

As shown by the cross-sectional view 3100 of FIG. 3100, the semiconductor layer 114 and the gate dielectric layer 112 may be formed over the structure shown by the cross-sectional view 3000 of FIG. 30A. As shown by the cross-sectional view 3200 of FIG. 32, a layer of the interlevel dielectric 159 may then be deposited and planarized to provide a level surface.

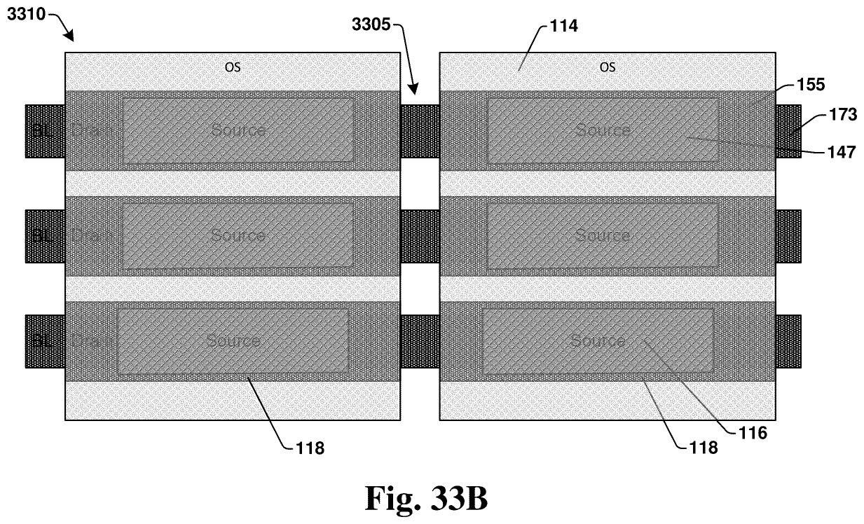

As shown by the cross-sectional view 3300 of FIG. 33A and the plan view 3310 of FIG. 33B, a mask 3301 may be formed and an etch process carried out that patterns the semiconductor layer 114. The etch may stop on the etch stop layer 165 so that the patterning process creates edges 509 of the drain electrodes 118 in addition to edges 507 of the semiconductor layers 114. The etch may form the gap 3305 and separate the drain electrode 118 on the right from the drain electrode 118 on the left. Alternatively, this separation may be achieved with the etch illustrated by the cross-sectional view 2800 of FIG. 28A and the plan view 2810 of FIG. 28B, however, in that alternative process the semiconductor layer 114 deposits in gap 3305. The present etch may then remove the semiconductor layer 114 from the gap 3305. But the illustrated process sequence in which the present etch separates the drain electrodes 118 allows for less etching of the semiconductor layer 114 and may provide a device that has lower leakage.

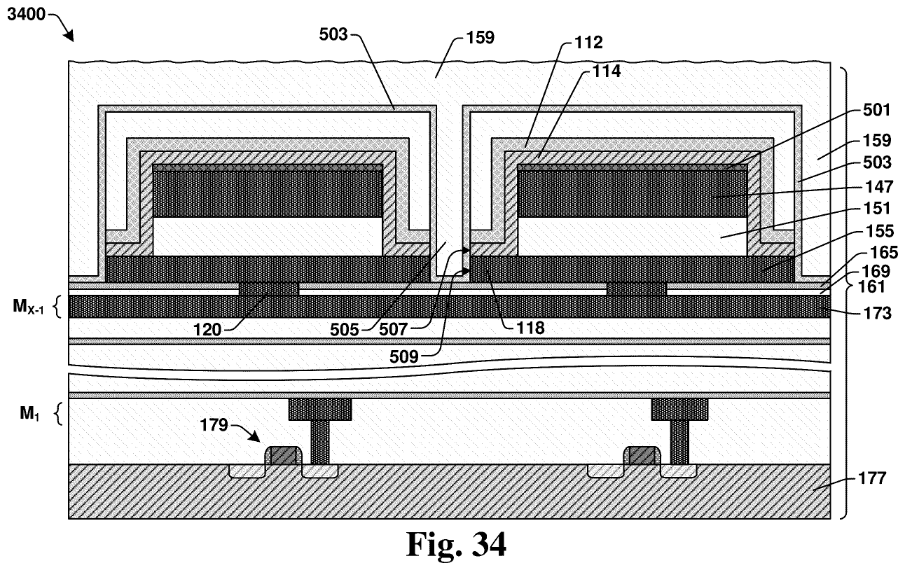

As shown by the cross-sectional view 3400 of FIG. 34, the high κ dielectric layer 503 and an additional layer of the interlevel dielectric 159 may be deposited over the structure shown by the cross-sectional view 3300 of FIG. 33A. The high κ dielectric layer 503 coats the edges 507 of the semiconductor layers 114 and edges 509 of the drain electrodes 118. The high K dielectric layer 503 may be as thin or thinner than the gate dielectric layer 112.

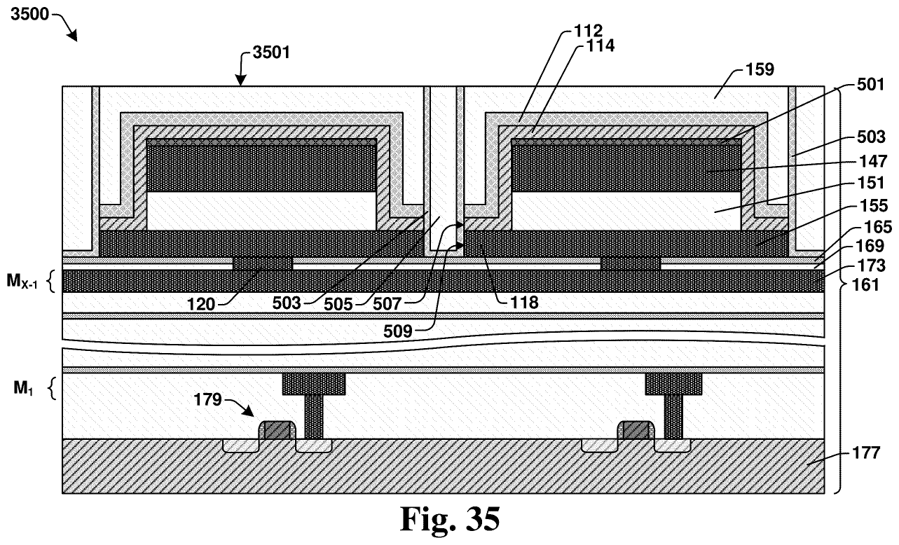

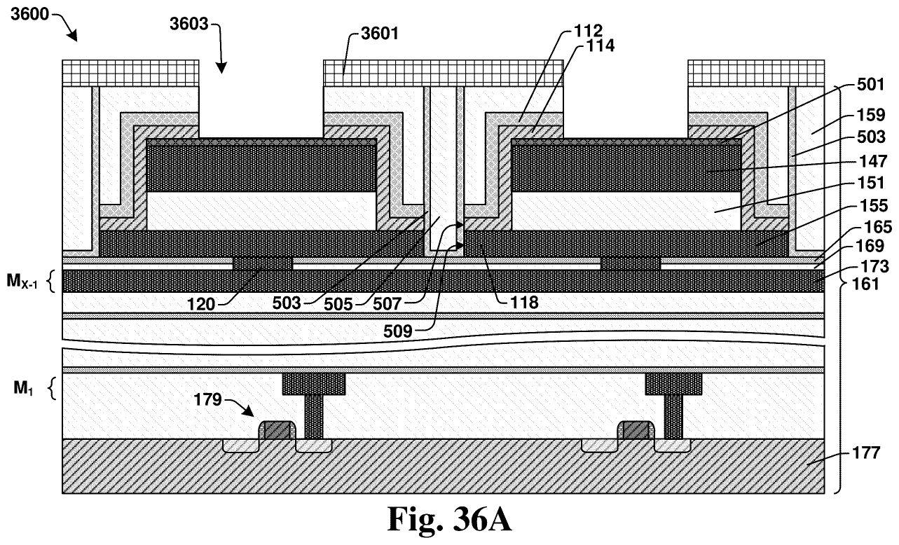

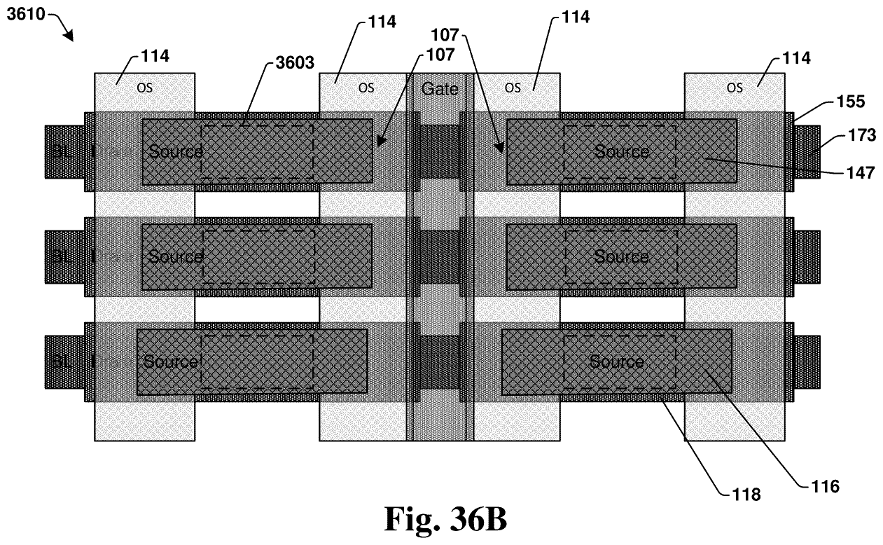

As shown by the cross-sectional view 3500 of FIG. 35, a planarization process such as CMP or the like may be carried out to provide a level surface 3501. As shown by the cross-sectional view 3600 of FIG. 36A and the plan view 3610 of FIG. 36B, a mask 3601 may be formed and an etch process carried out to form openings 3603. This etch may stop on the top metal layer 501.

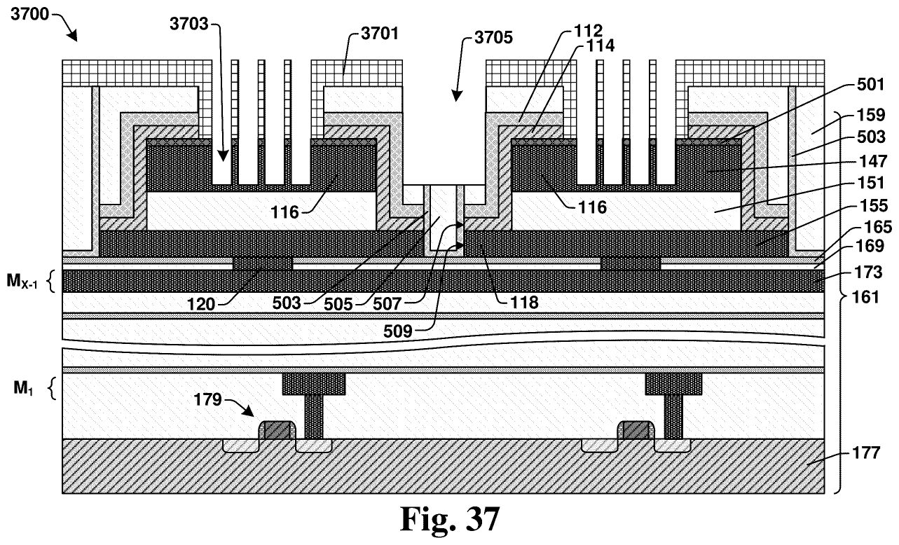

As shown by the cross-sectional view 3700 of FIG. 37, a mask 3701 may be formed and an etch process may be carried out to form pits 3703 in the source electrodes 116. This etch may also form the gap 3705 between the source electrodes 116. The etch may be a dry etch such as a plasma etch or the like.

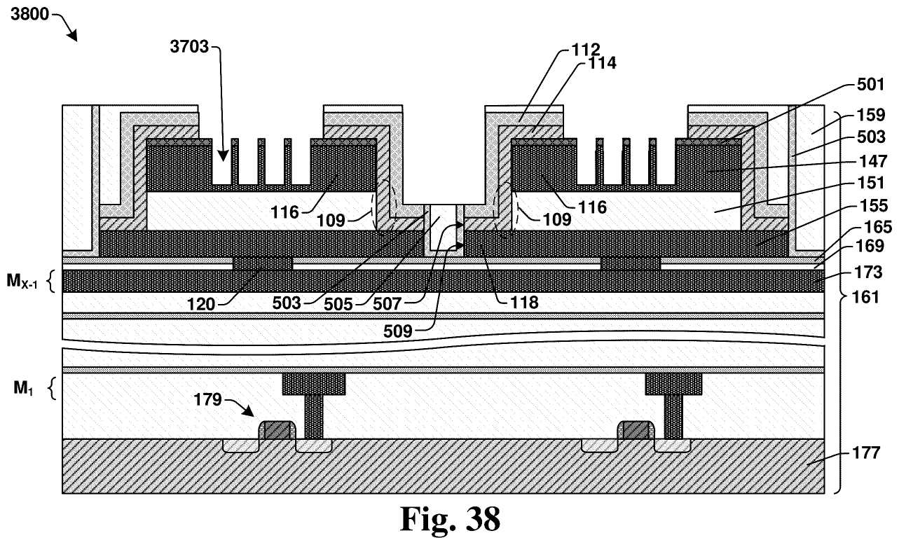

As shown by the cross-sectional view 3800 of FIG. 38, another etch may be carried out to expose the gate dielectric layer 112 over the channels 109. This etch process is selective for removing the interlevel dielectric 159 without damaging the gate dielectric layer 112. In some embodiments, this is a wet etch. The top metal layer 501 may protect the source electrodes 116 during this etch process.

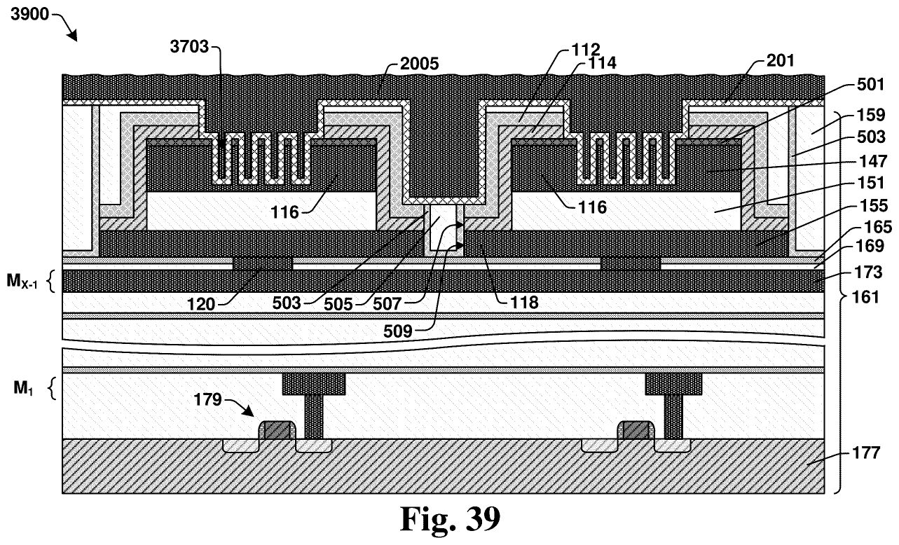

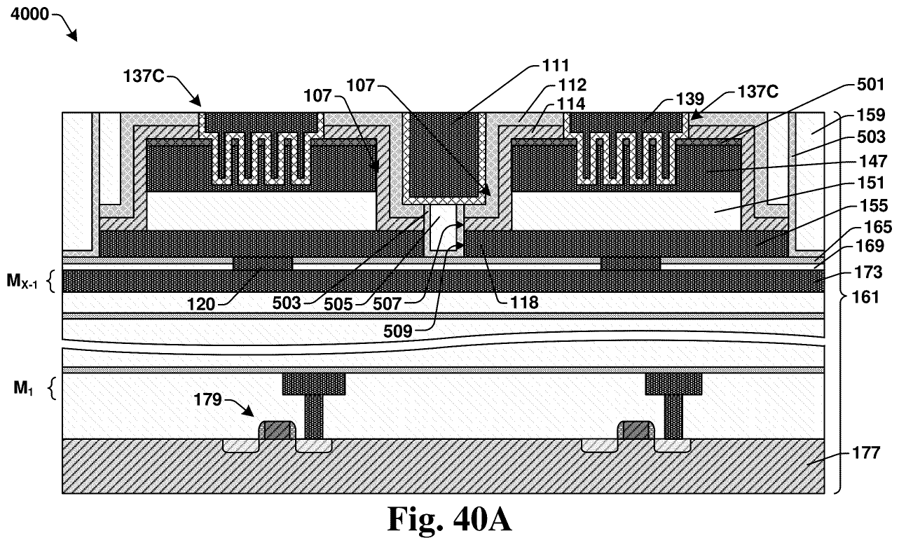

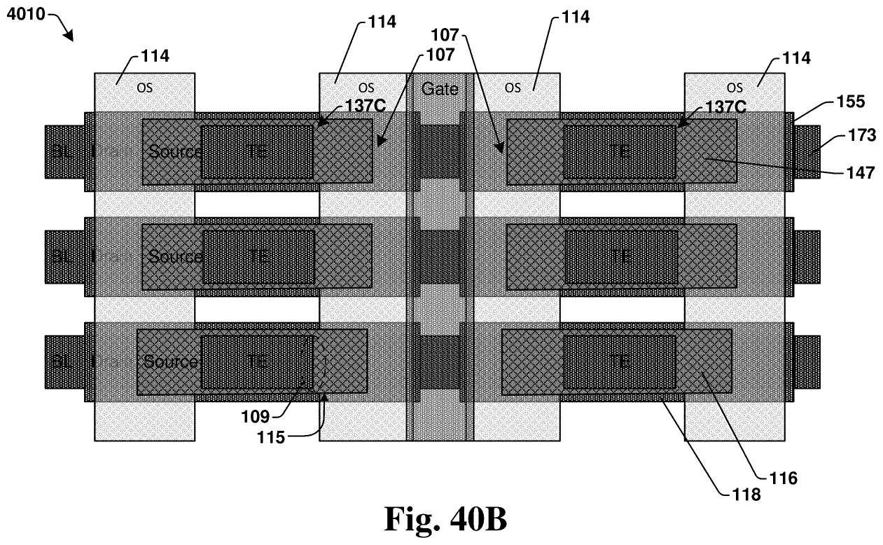

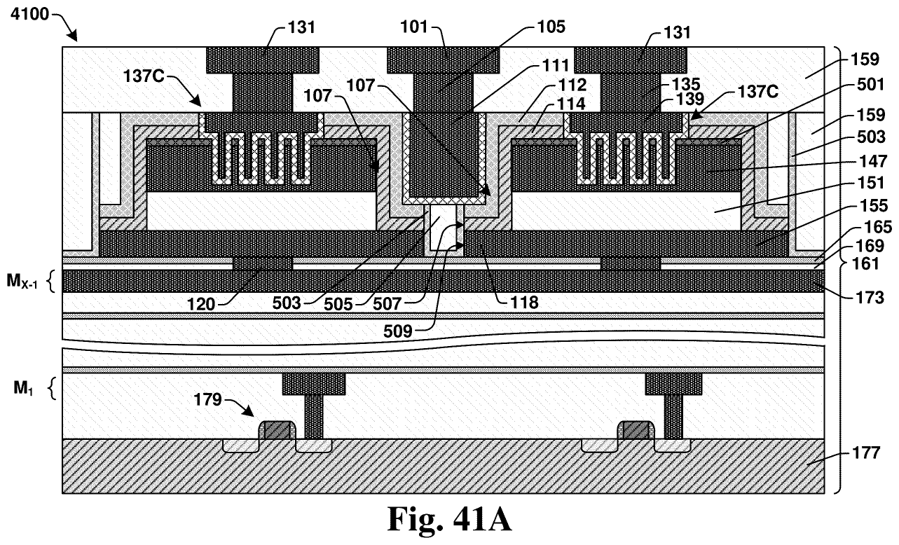

As shown by the cross-sectional view 3900 of FIG. 39, the internal structure 201 and the top electrode metal layer 2005 are deposited over the structure shown by the cross-sectional view 3800 of FIG. 38. The internal structure 201 and the top electrode metal layer 2005 fill the pits 3703 in the source electrodes 116. As shown by the cross-sectional view 4000 of FIG. 40A and the plan view 4010 of FIG. 40B, a planarization process such as CMP or the like may be carried out. After planarization, a first remaining portion of the top electrode metal layer 2005 provides the gate electrode 111 and a second remaining portion of the top electrode metal layer 2005 provides the top electrodes 139.

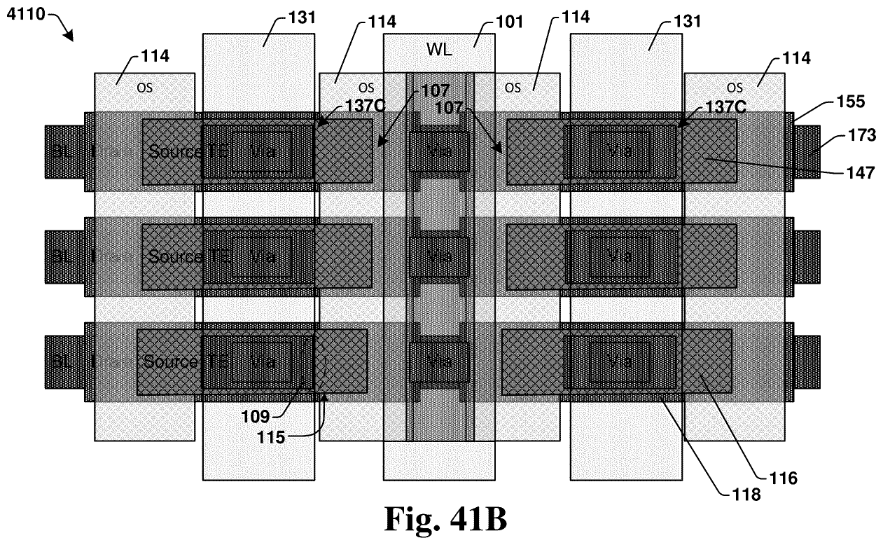

As shown by the cross-sectional view 4100 of FIG. 41A and the plan view 4110 of FIG. 41B, an additional layer of the interlevel dielectric 159 may be deposited and a dual damascene process carrier out to form the vias 105 and 135, the word lines 101, and the ground rails 131. Alternatively, the word lines 101 and or the ground rails 131 may be disposed in a subsequently formed metallization layer.

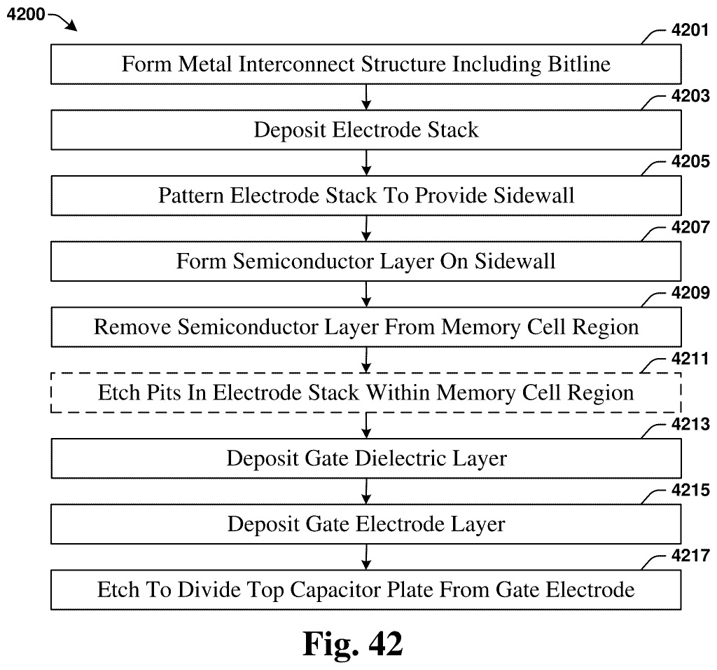

FIGS. 42-44 present flow chart for some processes that may be used to form an integrated circuit device according to the present disclosure. While the processes of FIG. 42-44 are illustrated and described herein as series of acts or events, it will be appreciated that the illustrated ordering of such acts or events is not to be interpreted in a limiting sense. For example, some acts may occur in different orders and or concurrently with other acts or events apart from those illustrated and or described herein. Further, not all illustrated acts are required to implement some aspects of the present disclosure or the embodiments thereof, and one or more of the acts depicted may be carried out in one or more separate acts and or phases.

The process 4200 of FIG. 42 may begin with act 4201, forming a metal interconnect structure including a bitline. The cross-sectional views 600 of FIGS. 6 and 2600 of FIG. 26 provide examples.

Act 4203 is depositing an electrode stack. The electrode stack includes two electrode layers separated by a spacer layer. The cross-sectional views 800 of FIGS. 8 and 2700 of FIG. 27 provide examples.

Act 4205 is patterning the electrode stack to provide a sidewall that includes the spacer layer. The cross-sectional views 1000 of FIGS. 10 and 300 of FIG. 30A provide examples.

Act 4207 is forming a semiconductor layer on the sidewall. The cross-sectional views 1100 of FIGS. 11 and 3100 of FIG. 31 provide examples.

Act 4209 is removing the semiconductor layer from a memory cell region. The memory cell region is a region where memory cells will be formed. The cross-sectional views 1200 of FIG. 12, 1800 of FIGS. 18, and 3600 of FIG. 36A provide examples. This step may be avoided if the semiconductor layer is provided by a selective growth process so that the semiconductor layer is not formed in the memory cell region.

Act 4211 is an optional step of etching pits in the electrode stack within the memory cell region. The depth of the pits may be limited to the uppermost electrode of the electrode stack. The cross-sectional views 2300 of FIGS. 23 and 3700 of FIG. 37 provide examples.

Act 4213 is depositing a gate dielectric layer. The cross-sectional views 1300 of FIG. 13, 3100 of FIG. 31 provide examples.

Act 4215 is depositing a gate electrode layer. The cross-sectional views 1300 of FIGS. 13 and 3900 of FIG. 39 provide examples.

Act 4217 is etching that separates the gate electrode layer from the top capacitor plate. The cross-sectional view 1400 of FIG. 14 provides an example.

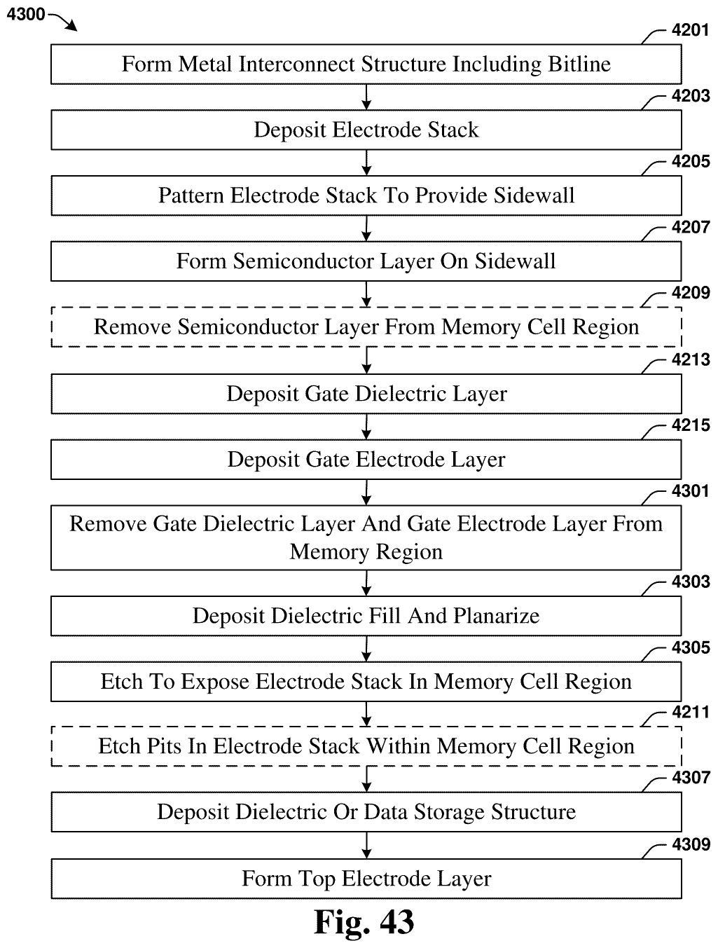

The process 4300 of FIG. 43 contains many of the same steps as the process 4200 of FIG. 42. The process 4300 differs beginning with act 4301, etching to remove the gate dielectric layer and the gate electrode layer from the memory region. The cross-sectional view 1800 of FIG. 18 provides an example of this alternative processing. Optional the semiconductor layer is removed from the memory cell region at this stage of processing rather than at an earlier stage.

Act 4303 is depositing a dielectric fill material and planarizing. The dielectric fill may be an interlevel dielectric. The cross-sectional views 1900 of FIGS. 19 and 3200 of FIG. 32 provide examples.

Act 4305 is etching to expose the electrode stack in the memory cell region. The cross-sectional views 2000 of FIGS. 20 and 3600 of FIG. 36A provide examples. Optionally, act 4211 is then carried out to form pits in the electrode stack.

Act 4307 is depositing the internal structure of a memory cell, which may be either a dielectric layer or a data storage structure. The cross-sectional views 2100 of FIG. 21, 2400 of FIGS. 24, and 3900 of FIG. 39 provide examples.

Act 4309 is forming the top electrode layer. The cross-sectional views 2100-2200 of FIG. 21-22 provide one example. The cross-sectional views 2400-2500 of FIG. 24-25 provide another example. The cross-sectional views 4000-4100 of FIG. 40A-41A provide a third example.

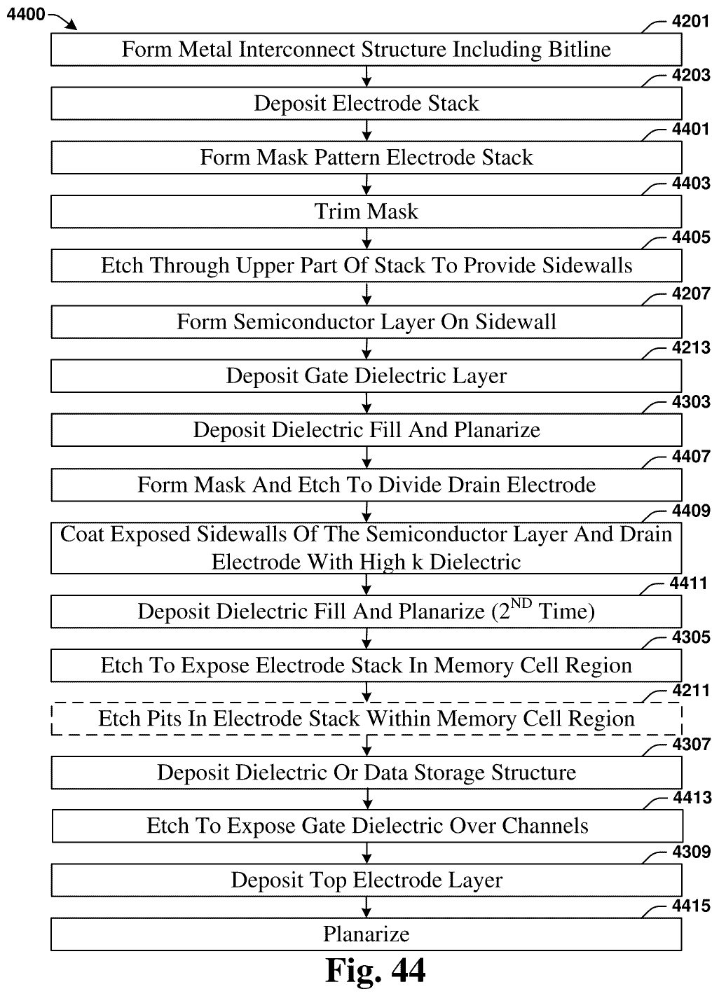

The process 4400 of FIG. 44 contains many of the same steps as the processes 4200 and 4300 of FIGS. 42 and 43. The process 4400 may differ beginning with act 4401, forming a mask and patterning the electrode stack. This patterning may define edges of the drain electrode. The cross-sectional view 2800 of FIG. 28A and the plan view 2810 of FIG. 28B provide an example.

Act 4403 is trimming the mask. The cross-sectional view 2900 of FIG. 29 provides an example. Act 4405 is using the trimmed mask to shape the source electrodes and to define sidewalls that include the spacer layer. The cross-sectional view 3000 of FIG. 30A and the plan view 3010 of FIG. 30B provide an example.

Act 4407 is forming a mask and carrying out an etch to divide two adjacent drain electrodes. The cross-sectional view 3300 of FIG. 33A and the plan view 3310 of FIG. 33B provide an example.

Act 4409 is coating exposed sidewalls of the semiconductor layer and the drain electrode with high κ dielectric. Act 4411 is depositing another dielectric layer and planarizing. The cross-sectional view 3400 of FIG. 34 provides an example.

With act 4305, the electrode stack is exposed in the memory cell regions. With act 4307, the internal structure of the memory cells is deposited.

Act 4413 is etching to expose the gate dielectric over the channels. The cross-sectional views 3700 of FIGS. 37 and 3800 of FIG. 38 provide an example.

The top electrode layer is deposited with act 4309. This deposition may also provide metal for the gate electrode. Act 4415 is planarizing the top electrode layer, which defines the gate electrode from this metal. The cross-sectional views 3900 of FIGS. 39 and 4000 of FIG. 40A provide an example of this processing.

Some aspects of the present disclosure relate to an integrated circuit device that include a metal interconnect structure over the semiconductor substrate. A first transistor disposed within the metal interconnect structure include a first source/drain electrode, a second source/drain electrode, a channel, a gate dielectric, and a gate electrode. The second source/drain electrode is vertically stacked over the first source/drain electrode and is separated from the first source/drain electrode by a dielectric spacer. The dielectric spacer has a sidewall extending from the second source/drain electrode to the first source/drain electrode. The channel is provided by a semiconductor layer that forms a coating on the sidewall. The gate dielectric is between the gate electrode and the channel.

In some embodiments, the semiconductor layer comprises an oxide semiconductor and the gate dielectric comprises a high κ dielectric. In some embodiments, the semiconductor layer extends above the second source/drain electrode. In some embodiments, the integrated circuit device further includes a second transistor. The second transistor shares the gate electrode with the first transistor, and the first transistor and the second transistor are symmetrical about the gate electrode.

In some embodiments, the integrated circuit device further includes a memory cell, wherein the second source/drain electrode extends laterally to provide a bottom electrode for the memory cell. In some embodiments, the dielectric spacer and the first source/drain electrode extend directly beneath the memory cell. In some embodiments, the memory cell is a capacitor. In some embodiments, the memory cell includes a distinct layer of material that has a composition and thickness equivalent to the gate dielectric. In some embodiments, the memory cell has a top electrode with a composition and thickness equivalent to the gate electrode. In some embodiments, the memory cell has a top electrode, and the top electrode and the gate electrode have coplanar upper surfaces. In some embodiments, the semiconductor layer extends to a height above the bottom electrode for the memory cell. In some embodiments, the metal interconnect structure comprises two adjacent metallization layers, and the first transistor and the memory cell are between the two adjacent metallization layers.

In some embodiments, the bottom electrode is pitted so that the memory cell has a three-dimensional structure. In some embodiments, the bottom electrode has internal sidewalls that define pits having elliptical horizontal cross-sections. In some embodiments, the bottom electrode has internal sidewalls that define pits having circular horizontal cross-sections. In some embodiments, the bottom electrode has internal sidewalls that define trenches.

Some aspects of the present disclosure relate to an integrated circuit device that include a metal interconnect structure over the semiconductor substrate. An electrode stack within the metal interconnect structure includes a second electrode layer over a dielectric spacer over a first electrode layer. The electrode stack has a sidewall comprising the second electrode layer and the dielectric spacer. An oxide semiconductor layer is over the sidewall. A gate stack is disposed over the oxide semiconductor layer. The gate stack includes a high κ dielectric layer, and a gate electrode. The electrode stack and the gate stack form a transistor for which the second electrode layer and the first electrode layer provide a source electrode and a drain electrode.

In some embodiments, the integrated circuit device further includes a memory cell having a data storage structure in direct contact with the second electrode layer. In some embodiments, the integrated circuit device further includes a memory cell having a dielectric layer in direct contact with the second electrode layer.

Some aspects of the present disclosure relate to a method of manufacturing an integrated circuit device that includes forming a metallization layer over a semiconductor, forming a first source/drain electrode layer over the metallization layer, forming a spacer layer over the first source/drain electrode layer, forming a second source/drain electrode layer over the spacer layer, and etching through the second source/drain electrode layer and the spacer layer. The etching forms a sidewall comprising the second source/drain electrode layer and the spacer layer. The method further includes forming a semiconductor layer that coats the sidewall, forming a gate dielectric layer over the semiconductor layer, and depositing a gate electrode layer over the gate dielectric layer.

In some embodiments, the method further includes masking the semiconductor layer in a first region while etching to remove the semiconductor layer from a second region prior to forming the gate dielectric layer. In some embodiments, forming the semiconductor layer includes a selective growth process so that the semiconductor layer forms in the first region but does not form in the second region. In some embodiments, the method further includes etching to pattern a stack comprising the first source/drain electrode layer, the spacer layer, and the second source/drain electrode layer using a first mask, trimming the first mask, and using the trimmed mask to form the sidewall.

In some embodiments, etching through the second source/drain electrode layer and the spacer layer forms a first source electrode and a second source electrode, and the method further includes depositing a first dielectric over the first source electrode and the second source electrode, etching a first opening between the first source electrode and the second source electrode, wherein the first opening extends through the first dielectric, the gate dielectric layer, and the semiconductor layer, etching the first opening forms a semiconductor layer sidewall, and etching the first opening exposes a first source/drain electrode layer sidewall, lining the first opening with a high κ dielectric layer, wherein the high κ dielectric layer covers the semiconductor layer sidewall and the first source/drain electrode layer sidewall, and filling the first opening with a second dielectric.

In some embodiments, etching the first opening divides a first portion of the first source/drain electrode layer into a first drain electrode and a second drain electrode. In some embodiments, the method further includes etching a second opening between the first source electrode and the second source electrode, wherein etching exposes the gate dielectric layer and the gate electrode layer deposits within the second opening. In some embodiments, etching the second opening comprises an etch process that is selective for etching the first dielectric compared to the high κ dielectric layer. In some embodiments, etching through the second source/drain electrode layer and the spacer layer forms a first source electrode and a second source electrode, and the method further includes depositing a first dielectric over the first source electrode and the second source electrode, and etching a first opening between the first source electrode and the second source electrode, wherein the first opening extends through the first dielectric, the gate dielectric layer, the semiconductor layer, and the first source/drain electrode layer, etching forms a semiconductor layer sidewall and a source/drain electrode layer sidewall, and the first opening divides a first portion of the first source/drain electrode layer beneath the first source electrode from a second portion of the second source/drain electrode layer beneath the second source electrode.

In some embodiments, the second source/drain electrode layer provides a bottom electrode for a memory cell in the second region. In some embodiments, the gate electrode layer provides a top electrode for the memory cell. In some embodiments, the memory cell is a capacitor, and the gate dielectric layer provides an insulating layer for the capacitor. In some embodiments, the method further includes etching a pit in the second source/drain electrode layer within the second region, wherein a top electrode of the memory cell extends into the pit. In some embodiments, depositing the gate electrode layer forms the top electrode.

In some embodiments, the method further includes etching to remove the gate electrode layer and the gate dielectric layer from the second region and forming a memory cell stack in the second region, wherein the second source/drain electrode layer provides a bottom electrode layer for the memory cell stack. In some embodiments, the method further includes etching a pit in the second source/drain electrode layer within the second region, wherein portions of the memory cell stack deposit within the pit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a semiconductor substrate;
a metal interconnect structure over the semiconductor substrate; and
a first transistor within the metal interconnect structure;
wherein the first transistor comprises a first source/drain electrode, a second source/drain electrode, a channel, a gate dielectric, and a gate electrode;
the second source/drain electrode is vertically stacked over the first source/drain electrode, and is separated from the first source/drain electrode by a dielectric spacer;
the dielectric spacer has a sidewall extending from the second source/drain electrode to the first source/drain electrode;
the channel is provided by a semiconductor layer that forms a coating on the sidewall; and
the gate dielectric is between the gate electrode and the channel.

2. The integrated circuit device of claim 1, wherein the semiconductor layer extends above the second source/drain electrode.

3. The integrated circuit device of claim 1, further comprising a second transistor, wherein the second transistor shares the gate electrode with the first transistor, and the first transistor and the second transistor are symmetrical about the gate electrode.

4. The integrated circuit device of claim 1, further comprising a memory cell, wherein the second source/drain electrode extends laterally to provide a bottom electrode for the memory cell.

5. The integrated circuit device of claim 4, wherein the dielectric spacer and the first source/drain electrode extend directly beneath the memory cell.

6. The integrated circuit device of claim 4, wherein the memory cell is a capacitor.

7. The integrated circuit device of claim 4, wherein the memory cell comprises a distinct layer that has a composition and thickness equivalent to the gate dielectric.

8. The integrated circuit device of claim 4, wherein the memory cell comprises a top electrode that has a composition and thickness equivalent to the gate electrode.

9. The integrated circuit device of claim 4, wherein the memory cell comprises a top electrode, and the top electrode and the gate electrode have coplanar upper surfaces.

10. The integrated circuit device of claim 4, wherein the semiconductor layer extends to a height above the bottom electrode for the memory cell.

11. The integrated circuit device of claim 4, wherein the metal interconnect structure comprises two adjacent metallization layers, and the first transistor and the memory cell are between the two adjacent metallization layers.

12. The integrated circuit device of claim 4, wherein the bottom electrode is pitted so that the memory cell has a three-dimensional structure.

13. An integrated circuit device, comprising:
a semiconductor substrate;
a metal interconnect structure over the semiconductor substrate;
an electrode stack comprising a second electrode layer over a dielectric spacer over a first electrode layer, wherein the electrode stack is within the metal interconnect structure and has a sidewall comprising the second electrode layer and the dielectric spacer;
an oxide semiconductor layer over the sidewall; and
a gate stack comprising, a high κ dielectric layer, and a gate electrode, wherein the gate stack is disposed over the oxide semiconductor layer;
wherein the electrode stack and the gate stack form a transistor for which the second electrode layer and the first electrode layer provide a source electrode and a drain electrode.

14. The integrated circuit device of claim 13, further comprising a memory cell having a data storage structure in direct contact with the second electrode layer.

15. A method of manufacturing an integrated circuit device, the method comprising:
forming a metallization layer over a semiconductor substrate that comprises a first region and a second region;
forming a first source/drain electrode layer over the metallization layer;
forming a spacer layer over the first source/drain electrode layer;
forming a second source/drain electrode layer over the spacer layer;
forming a first mask;
etching through the second source/drain electrode layer and the spacer layer, wherein the etching forms a sidewall aligned to an edge of the first mask, the sidewall comprises the second source/drain electrode layer and the spacer layer, and the sidewall is in the first region;
forming a semiconductor layer that coats the sidewall;
forming a gate dielectric layer over the semiconductor layer; and
depositing a gate electrode layer over the gate dielectric layer.

16. The method of claim 15, further comprising masking the semiconductor layer in the first region while etching to remove the semiconductor layer from the second region prior to forming the gate dielectric layer.

17. The method of claim 15, wherein forming the semiconductor layer comprises a selective growth process so that the semiconductor layer forms in the first region but does not form in the second region.

18. The method of claim 15, wherein the second source/drain electrode layer provides a bottom electrode for a memory cell in the second region.

19. The method of claim 18, wherein the gate electrode layer provides a top electrode for the memory cell.

20. The method of claim 18, wherein the memory cell is a capacitor, and the gate dielectric layer provides an insulating layer for the capacitor.
